(19) United States
(12) Patent Application Publication
(10) Pub. No.: US 2025/0338045 A1
(43) Pub. Date: Oct. 30, 2025

(54) STACKED CMOS IMAGE SENSOR COMPRISING A PIXEL SENSOR FOR HIGH CONVERSION GAIN AND METHOD FOR FORMING THE SAME

(71) Applicant: Taiwan Semiconductor Manufacturing Company, Ltd., Hsinchu (TW)

(72) Inventors: Chih-Kuan Yu, Nantou County (TW); Feng-Chi Hung, Chu-Bei City (TW); Wen-I Hsu, Tainan City (TW); Bing Cheng You, Taichung City (TW); Jen-Cheng Liu, Hsin-Chu City (TW); Dun-Nian Yaung, Taipei City (TW)

(21) Appl. No.: 19/263,589

(22) Filed: Jul. 9, 2025

Related U.S. Application Data
(63) Continuation of application No. 18/406,526, filed on Jan. 8, 2024.
(60) Provisional application No. 63/594,448, filed on Oct. 31, 2023.

(51) Int. Cl. H04N 25/79; H10F 39/00; H10F 39/18

(52) U.S. Cl. CPC H04N 25/79; H10F 39/014; H10F 39/18; H10F 39/802; H10F 39/8037; H10F 39/811

(57) ABSTRACT

Various embodiments of the present disclosure are directed to a stacked complementary metal-oxide semiconductor (CMOS) image sensor. A first integrated circuit (IC) chip and a second IC chip are vertically stacked. A pixel sensor spans the first and second IC chips. The pixel sensor comprises a first transfer transistor and a photodetector that are at the first IC chip, and further comprises a source-follower transistor, a transistor capacitor, and a second transfer transistor that are at the second IC chip. The transistor capacitor and the second transfer transistor are electrically coupled in series from a source/drain region of the first transfer transistor to a gate electrode of the source-follower transistor.

### REFERENCE TO RELATED APPLICATIONS

This application is a Continuation of U.S. application Ser. No. 18/406,526, filed on Jan. 8, 2024, which claims the benefit of U.S. Provisional Application No. 63/594,448, filed on Oct. 31, 2023. The contents of the above-referenced patent applications are hereby incorporated by reference in their entirety.

### BACKGROUND

Integrated circuits (ICs) with image sensors are used in a wide range of modern-day electronic devices, such as, for example, cameras, cell phones, and the like. Types of image sensors include, for example, complementary metal-oxide semiconductor (CMOS) image sensors and charge-coupled device (CCD) image sensors. Compared to CCD image sensors, CMOS image sensors are increasingly favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of some embodiments of a stacked complementary metal-oxide semiconductor (CMOS) image sensor comprising a pixel sensor for high conversion gain (HCG) arranged across a first integrated circuit (IC) chip and a second IC chip.

FIG. 2 illustrates a signal timing diagram for some embodiments of the pixel sensor of FIG. 1.

FIGS. 3A-3C illustrate electric potential diagrams for some embodiments of the pixel sensor of FIG. 1 at various times.

FIGS. 4A and 4B illustrate circuit diagrams of some alternative embodiments of the stacked CMOS image sensor of FIG. 1 in which the pixel sensor is varied.

FIG. 5 illustrates a circuit diagram of some embodiments of the stacked CMOS image sensor of FIG. 1 in which the stacked CMOS image sensor further comprises a third IC chip with an application-specific integrated circuit (ASIC).

FIG. 6 illustrates a schematic cross-sectional view of some embodiments of the stacked CMOS image sensor of FIG. 5.

FIG. 7 illustrates a schematic cross-sectional view of some alternative embodiments of the stacked CMOS image sensor of FIG. 5 in which the stacked CMOS image sensor comprises a plurality of pixel sensors.

FIG. 8 illustrates a top layout view of some embodiments of the stacked CMOS image sensor of FIG. 7.

FIG. 9 illustrates a top layout view of some first embodiments of the stacked CMOS image sensor of FIG. 1 at the second IC chip.

FIGS. 10A-10C illustrate cross-sectional views of some first embodiments of the stacked CMOS image sensor of FIG. 9.

FIGS. 11A-11C illustrate cross-sectional views of some second embodiments of the stacked CMOS image sensor of FIG. 9.

FIG. 12 illustrates a cross-sectional view of some embodiments of the stacked CMOS image sensor of FIG. 9 at both the first IC chip and the second IC chip.

FIG. 13 illustrates a top layout view of some second embodiments of the stacked CMOS image sensor of FIG. 1 at the second IC chip.

FIGS. 14A-14C illustrate cross-sectional views of some first embodiments of the stacked CMOS image sensor of FIG. 13.

FIGS. 15A-15C illustrate cross-sectional views of some second embodiments of the stacked CMOS image sensor of FIG. 13.

FIG. 16 illustrates a cross-sectional view of some embodiments of the stacked CMOS image sensor of FIG. 13 at both the first IC chip and the second IC chip.

FIG. 17 illustrates a cross-sectional view of some embodiments of a stacked CMOS image sensor comprising a plurality of pixel sensors each as in FIG. 12 and further comprising a third IC chip with an ASIC.

FIG. 18 illustrates a cross-sectional view of some alternative embodiments of the stacked CMOS image sensor of FIG. 17.

FIGS. 19A through 35B illustrate a series of views of some embodiments of a method for forming a stacked CMOS image sensor comprising a pixel sensor for HCG.

FIG. 36 illustrates a block diagram of some embodiments of the method of FIGS. 19A through 35B.

FIGS. 37 through 42B illustrate a series of views of some first alternative embodiments of the method of FIGS. 19A through 35B.

FIGS. 43A through 46B illustrate a series of views of some second alternative embodiments of the method of FIGS. 19A through 35B.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacked complementary metal-oxide semiconductor (CMOS) image sensor may comprise a first integrated circuit (IC) chip, a second IC chip, and a pixel sensor. The pixel sensor repeats to form a pixel array and comprises a pinned photodiode (PPD) and a plurality of readout devices. The readout devices comprise a transfer transistor and a source-follower transistor. The PPD is configured to accumulate photo-generated charge, and the transfer transistor is configured to selectively transfer the photo-generated charge to a floating diffusion node. The source-follower transistor has a gate electrode electrically coupled to the floating diffusion node and is configured to convert charge at the gate electrode to an output voltage.

The first and second IC chips are vertically stacked and accommodate the pixel sensor. The PPD, the transfer transistor, and the floating diffusion node are in the first IC chip, and the remainder of the readout devices are in the second IC chip. Arranging some of the readout devices in the second IC chip, as opposed to arranging all of the readout devices in the first IC chip, frees up space in the first IC chip. This allows the pixel sensor to be decreased in size without decreasing the size of the PPD and without compromising full well capacity (FWC). Hence, arranging some of the readout devices in the second IC chip allows pixel density of the stacked CMOS image sensor to be increased without compromising FWC.

While arranging some of the readout devices in the second IC chip allows increased pixel density without compromising FWC, it also leads to a long conductive path from the floating diffusion node to the gate electrode of the source-follower transistor. Because of its length, the long conductive path has a large amount of parasitic capacitance that increases capacitance at the gate electrode. Further, the long conductive path electrically couples parasitic capacitance at the floating diffusion node to the gate electrode. The increased capacitance at the gate electrode degrades a conversion gain of the source-follower transistor because the conversion gain is inversely proportional to the capacitance at the gate electrode. The degraded conversion gain, in turn, degrades low-light performance.

Various embodiments of the present disclosure are directed to a stacked CMOS image sensor comprising a pixel sensor for high conversion gain (HCG) and a method for forming the stacked CMOS image sensor. The pixel sensor comprises a PPD and a plurality of readout devices. Further, the readout devices comprise a PPD transfer transistor, a transistor capacitor, a capacitor transfer transistor, and a source-follower transistor.

The PPD and the PPD transfer transistor are at a first IC chip, and the PPD transfer transistor is configured to selectively transfer photo-generated charge from the PPD to a first floating diffusion node. The remainder of the readout devices are at the second IC chip, and a gate electrode of the source-follower transistor is electrically coupled to a second FDN. Further, the capacitor transfer transistor and the transistor capacitor are electrically coupled in series from the second floating diffusion node to the first floating diffusion node, such that the transistor capacitor separates the capacitor transfer transistor from the first floating diffusion node. The transistor capacitor is configured to selectively store charge from the first floating diffusion node, and the capacitor transfer transistor is configured to selectively transfer charge from the transistor capacitor to the second floating diffusion node.

By electrically separating the second floating diffusion node from the first floating diffusion node, the transistor capacitor and the capacitor transfer transistor isolate the second floating diffusion node from parasitic capacitance at the first floating diffusion node and along a long conductive path extending from the first floating diffusion node to the transistor capacitor. As a result, parasitic capacitance at the second floating diffusion node and hence at the gate electrode of the source-follower transistor is decreased. This, in turn, leads to a HCG at the source-follower transistor and increases low-light performance. Further, arranging some of the readout devices in the second IC chip, as opposed to arranging all of the readout devices in the first IC chip, allows the size of the pixel sensor to be decreased without decreasing the size of the PPD. This, in turn, allows increased pixel density without compromising FWC.

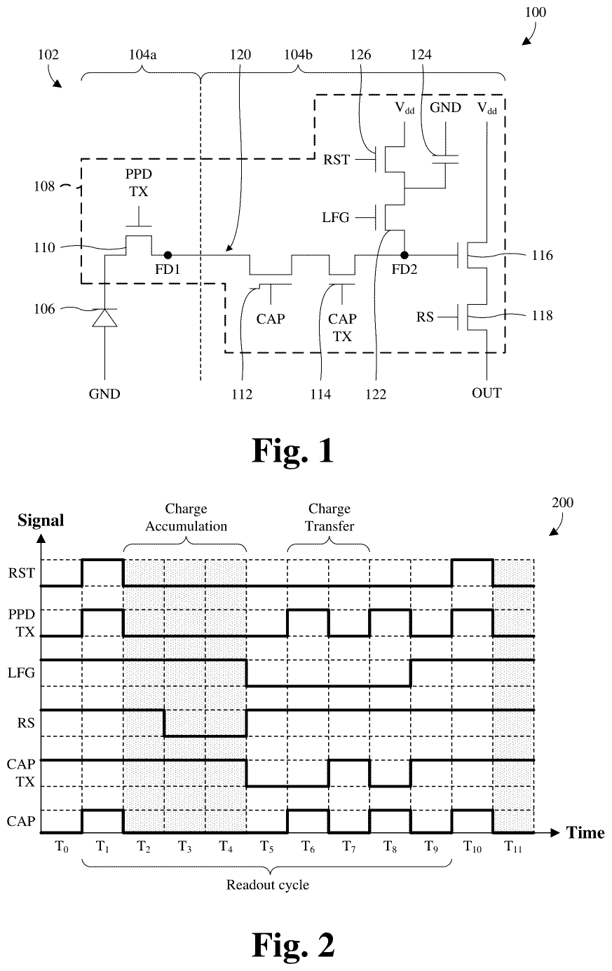

With reference to FIG. 1, a circuit diagram 100 of some embodiments of a stacked CMOS image sensor comprising a pixel sensor 102 for HCG is provided. The pixel sensor 102 spans a first IC chip 104a and a second IC chip 104b that are stacked. The first and second IC chips 104a, 104b are shown as being laterally stacked, but may alternatively be vertically stacked. The pixel sensor 102 may, for example, be an active pixel sensor (APS) with a lateral overflow integration capacitor (LOFIC) architecture or some other suitable architecture. Further, the pixel sensor 102 may, for example, also be known as a pixel or the like.

The pixel sensor 102 comprises a PPD 106 and a plurality of readout devices 108 configured to facilitate readout of the PPD 106. In alternative embodiments, the PPD 106 is some other suitable type of photodetector. The readout devices 108 comprise, among other things, a PPD transfer transistor 110, a transistor capacitor 112, a capacitor transfer transistor 114, a source-follower transistor 116, and a row-select transistor 118. The PPD 106 and the PPD transfer transistor 110 are at the first IC chip 104a, and the remainder of the readout devices 108 are at the second IC chip 104b. Arranging some of the readout devices 108 at the second IC chip 104b, as opposed to arranging all of the readout devices 108 at the first IC chip 104a, allows the size of the pixel sensor 102 to be decreased without decreasing the size of the PPD 106. This, in turn, allows increased pixel density without compromising FWC.

The PPD transfer transistor 110 is configured to selectively transfer photo-generated charge from the PPD 106 to a first floating diffusion node FD1. The source-follower transistor 116 is gated by charge at a second floating diffusion node FD2. The transistor capacitor 112 and the capacitor transfer transistor 114 are electrically coupled in series from the second floating diffusion node FD2 to the first floating diffusion node FD1, such that the transistor capacitor 112 separates the capacitor transfer transistor 114 from the first floating diffusion node FD1. The transistor capacitor 112 is configured to selectively store charge from the first floating diffusion node FD1, and the capacitor transfer transistor 114 is configured to selectively transfer charge from the transistor capacitor 112 to the second floating diffusion node FD2.

By electrically separating the second floating diffusion node FD2 from the first floating diffusion node FD1, the transistor capacitor 112 and the capacitor transfer transistor 114 isolate the second floating diffusion node FD2 from parasitic capacitance at the first floating diffusion node FD1 and at a long conductive path 120 extending from the first floating diffusion node FD1 to the transistor capacitor 112. Hence, parasitic capacitance at the second floating diffusion node FD2 and the gate electrode of the source-follower transistor 116 is decreased. The decreased parasitic capacitance increases a conversion gain of the source-follower transistor 116, which, in turn, increases low-light performance of the pixel sensor 102.

The source-follower transistor 116 is gated by charge at the second floating diffusion node FD2, as described above, and is electrically coupled from power V_{dd} to the row-select transistor 118. Further, the source-follower transistor 116 is configured to convert the charge to an output signal having a voltage that follows or is otherwise proportional to the charge. The row-select transistor 118 is gated by a row-select signal RS and is configured to selectively pass the output signal to an output OUT of the pixel sensor 102.

A conversion gain of the source-follower transistor 116 is inversely proportional to capacitance at the gate electrode of the source-follower transistor 116. For example, V/Q˜1/C, wherein V is the voltage of the output signal, Q is the charge, V/Q is the conversion gain, and C is the capacitance. Therefore, by decreasing parasitic capacitance at the gate electrode, the transistor capacitor 112 and the capacitor transfer transistor 114 increase a conversion gain of the source-follower transistor 116, such that the source-follower transistor 116 may have HCG. This, in turn, may increase low-light performance of the pixel sensor 102.

The transistor capacitor 112 is gated by a capacitor signal CAP, and the capacitor transfer transistor 114 is gated by a capacitor transfer signal CAP TX. Further, the transistor capacitor 112 has a gate dielectric layer with a stepped thickness, as schematically illustrated by the stepped profile of a gate electrode of the transistor capacitor 112.

The stepped thickness of the transistor capacitor 112 steps down from a first side of the transistor capacitor 112 that is electrically coupled to the first floating diffusion node FD1 to a second side of the transistor capacitor 112, opposite the first side, that is electrically coupled to the capacitor transfer transistor 114. As seen hereafter, the stepped thickness leads to a stepped electric potential that creates a barrier to prevent charge at the transistor capacitor 112 from moving back to the first floating diffusion node FD1.

The PPD 106 and the PPD transfer transistor 110 are electrically coupled in series from the first floating diffusion node FD1 to ground GND. A cathode of the PPD 106 is electrically coupled to the PPD transfer transistor 110, whereas an anode of the PPD 106 is electrically coupled to ground GND. The PPD 106 is configured to accumulate photo-generated charge (e.g., electrons) in response to incident light. The PPD transfer transistor 110 is electrically coupled to the first floating diffusion node FD1 and is gated by a PPD transfer signal PPD TX. Further, as above, the PPD transfer transistor 110 is configured to selectively transfer photo-generated charge from the PPD 106 to the first floating diffusion node FD1.

The readout devices 108 further comprises an LOFIC transistor 122, a LOFIC 124, and a reset transistor 126 that are electrically coupled to a common node. The LOFIC transistor 122 is gate by a LOFIC signal LFG and is electrically coupled from the common node to the second floating diffusion node FD2. The LOFIC 124 is electrically coupled from the common node to ground GND. The reset transistor 126 is gated by a reset signal RST and is electrically coupled from the common node to power V_{dd}.

Before charge is accumulated in the PPD 106, the reset transistor 126 and the LOFIC transistor 122, with coordination with the PPD transfer transistor 110, the transistor capacitor 112, and the capacitor transfer transistor 114, are configured to electrically couple the PPD 106 to power V_{dd} to reset the PPD 106 to a pinning voltage. During use of the pixel sensor 102 in a high-light environment, the LOFIC transistor 122, with coordination with the PPD transfer transistor 110, the transistor capacitor 112, and the capacitor transfer transistor 114, is configured to electrically couple the PPD 106 to the LOFIC 124 to transfer excess charge from the PPD 106 to the LOFIC 124. Such excess charge corresponds to charge beyond a saturation level of the PPD 106, such that transferring excess charge prevents blooming.

In some embodiments, the transistors of the readout devices 108 are metal-oxide-semiconductor field-effector transistors (MOSFETs), fin field-effect transistors (FinFETs), gate-all-around field-effect transistors (GAA FETs), nanosheet field-effect transistors, the like, or any combination of the foregoing. In some embodiments, the transistor capacitor 112 has a structure of MOSFET or the like and/or is a MOSFET or the like. Further, in some embodiments, the transistor capacitor 112 has a structure of a capacitor in a charge-coupled device (CCD) pixel sensor and/or is a metal-oxide-semiconductor (MOS) capacitor or the like. In some embodiments, the transistor capacitor 112 has a capacitance of about 0.1 picofarad (pF) to 10 femtofarad (fF) or some other suitable capacitance.

In some embodiments, the readout devices 108 at the second IC chip 104b may be regarded as an in-pixel circuit or the like. In some embodiments, the transistor capacitor 112 may be regarded as a MOS capacitor or the like. In some embodiments, the capacitor transfer transistor 114 may be regarded as an HCG transistor or the like.

With reference to FIG. 2, a signal timing diagram 200 for some embodiments of the pixel sensor 102 of FIG. 1 is provided. The horizontal axis corresponds to time and is broken into 12 time periods respectively labeled T₀, T₁, and so on to T₁₁. Time periods T₁-T₉ correspond to a readout cycle. Time period T₀ corresponds to a previous readout cycle (partially shown) and time periods T₁₀ and T₁₁ correspond to a subsequent readout cycle (partially shown).

The vertical axis corresponds to signals at individual gate electrodes of the readout devices 108 in FIG. 1. The signals include the reset signal RST, the PPD transfer signal PPD TX, the LOFIC signal LFG, the row-select signal RS, the capacitor transfer signal CAP TX, and the capacitor signal CAP. Further, each signal has a high state corresponding to an ON (e.g., conducting) state of a corresponding readout device, and further has a low state corresponding to an OFF (e.g., non-conducting) state of the corresponding readout device.

At time period T₁, the pixel sensor 102 is reset. This includes, among other things, setting the PPD 106 to its pinning voltage. The reset signal RST, the PPD transfer signal PPD TX, and the capacitor signal CAP are pulsed to high states. Further, the LOFIC signal LFG and the capacitor transfer signal CAP TX persist at high states. As a result, the PPD transfer transistor 110, the transistor capacitor 112, the capacitor transfer transistor 114, the LOFIC transistor 122, and the reset transistor 126 are in ON states and collectively form a conductive path electrically coupling the PPD 106 to power V_{dd}.

At time periods T₂-T₄, the PPD 106 accumulates charge in response to incident light. The PPD transfer signal PPD TX is in a low state throughout time periods T₂-T₄, whereby the PPD transfer transistor 110 is in an OFF state throughout time periods T₂-T₄. This provides a barrier to prevent the charge from moving out of the PPD 106.

While the capacitor signal CAP and the PPD transfer signal PPD TX are at low states throughout time periods T₂-T₄, the capacitor signal CAP and the PPD transfer signal PPD TX may alternatively be pulsed to high states. In such alternative embodiments, the transistor capacitor 112, the PPD transfer transistor 110, the capacitor transfer transistor 114, and the LOFIC transistor 122 would be in ON states. This would result in a conductive path to transfer excess charge from the PPD 106 to the LOFIC 124 to prevent saturation of the PPD 106 and blooming during use of the pixel sensor 102 in a high-light environment.

At time period T₅, accumulation of charge has concluded and there is a delay before charge transfer. The signals are in low states except for the row-select signal RS.

At time period T₆, charge that accumulated at the PPD 106 is transferred from the PPD 106 to the transistor capacitor 112. The PPD transfer signal PPD TX and the capacitor signal CAP are pulsed to high states, while the capacitor transfer signal CAP TX persists at a low state. As such, the PPD transfer transistor 110 and the transistor capacitor 112 are in ON states, while the capacitor transfer transistor 114 is in an OFF state.

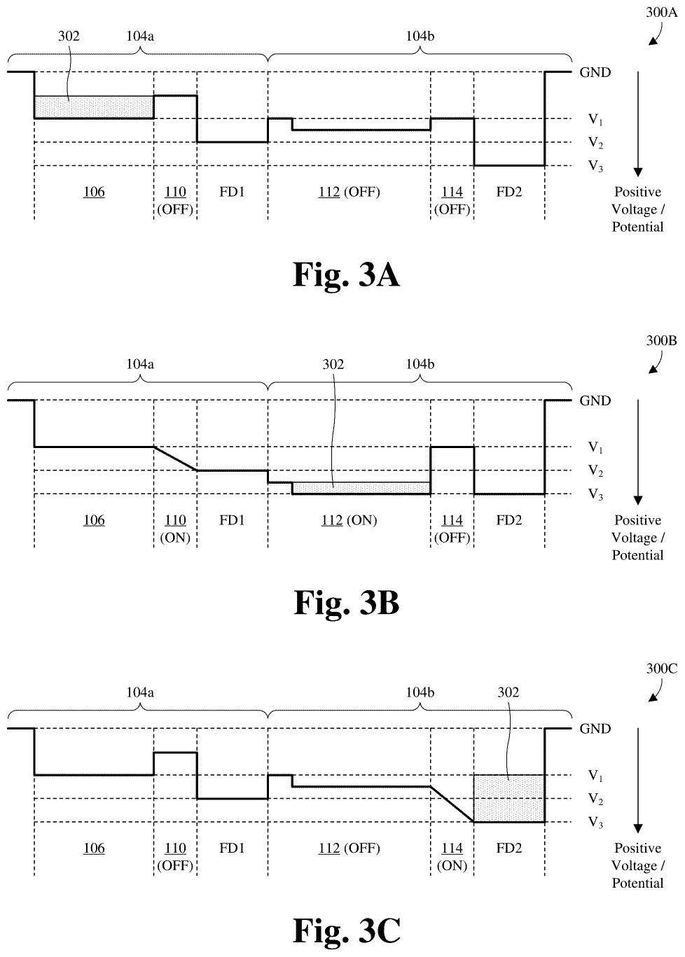

As seen hereafter at FIG. 3B, the ON state of the PPD transfer transistor 110 and the ON state of the transistor capacitor 112 create an electric potential difference from the PPD 106 to the transistor capacitor 112 that moves the charge from the PPD 106 to the transistor capacitor 112. Further, the OFF state of the capacitor transfer transistor 114 creates a barrier that prevents the charge from moving to the second floating diffusion node FD2.

At time period T₇, the charge at the transistor capacitor 112 is transferred to the second floating diffusion node FD2. The capacitor transfer signal CAP TX is pulsed to a high state, while the transistor capacitor 112 is in a low state. As such, the capacitor transfer transistor 114 is in an ON state, whereas the transistor capacitor 112 is in an OFF state.

As seen hereafter at FIG. 3C, the OFF state of the transistor capacitor 112 and the ON state of the capacitor transfer transistor 114 create an electric potential difference from the transistor capacitor 112 to the second floating diffusion node FD2 that moves the charge from the transistor capacitor 112 to the second floating diffusion node FD2. Further, the transistor capacitor 112 has a stepped gate dielectric thickness that creates a stepped electric potential. The stepped electric potential creates a barrier preventing the charge from moving from the transistor capacitor 112 to the first floating diffusion node FD1.

At time period T₈, the charge at the second floating diffusion node FD2 is converted to an output signal having a voltage that follows or is otherwise proportional to the charge. Further, the row-select transistor 118 passes the output signal to an output OUT of the pixel sensor 102. The row-select signal RS persists at a high state, such that the row-select transistor 118 is in an ON state. Further, the capacitor transfer signal CAP TX is in a low state, such that the capacitor transfer transistor 114 is in an OFF state. The ON state of the row-select transistor 118 passes the output signal from the source-follower transistor 116 to the output OUT. The OFF state of the capacitor transfer transistor 114 creates a barrier to prevent the charge from moving out of the second floating diffusion node FD2.

By electrically separating the second floating diffusion node FD2 from the first floating diffusion node FD1, the transistor capacitor 112 and the capacitor transfer transistor 114 isolate the second floating diffusion node FD2 from parasitic capacitance at the first floating diffusion node FD1 and the long conductive path 120 extending from the first floating diffusion node FD1 to the transistor capacitor 112. Hence, parasitic capacitance at the second floating diffusion node FD2 and the gate electrode of the source-follower transistor 116 is decreased. The decreased parasitic capacitance increases a conversion gain of the source-follower transistor 116, which, in turn, increases low-light performance of the pixel sensor 102.

At time period T₉, readout of charge has concluded and there is a delay before a next readout cycle. The reset signal RST, the PPD transfer signal PPD TX, and the capacitor signal CAP are in low states, whereas the LOFIC signal LFG, the row-select signal RS, and the capacitor transfer signal CAP TX are in high states.

With reference to FIGS. 3A-3C, potential diagrams 300A-300C for some embodiments of the pixel sensor 102 of FIG. 1 are provided respectively at times period T₅, T₆, and T₇ in FIG. 2. The horizontal axis corresponds to location within the pixel sensor 102. The vertical axis corresponds to electric potential, which increases vertically downward from ground GND.

Focusing on FIG. 3A, charge 302 has accumulated at the PPD 106 and the PPD 106 has an electric potential at a first voltage V₁. Such accumulation may, for example, occur during time periods T₂-T₄ in FIG. 2. Further, the PPD transfer transistor 110, the transistor capacitor 112, and the capacitor transfer transistor 114 are in OFF states. Because the PPD transfer transistor 110 is in an OFF state, an electric potential at the PPD transfer transistor 110 is elevated relative to the electric potential at the PPD 106. This creates a barrier that prevents the charge 302 from moving out of the PPD 106 to the first floating diffusion node FD1.

Focusing on FIG. 3B, the charge 302 is moved from the PPD 106 to the transistor capacitor 112. The PPD transfer transistor 110 and the transistor capacitor 112 are in ON states, and the capacitor transfer transistor 114 is in OFF states.

Because the PPD transfer transistor 110 is in an ON state, an electric potential at the PPD transfer transistor 110 is between the electric potential at the PPD 106 (e.g., the first voltage V₁) and an electric potential at the first floating diffusion node FD1 (e.g., a second voltage V₂). Further, because the transistor capacitor 112 is in an ON state, an electric potential at the transistor capacitor 112 (e.g., a third voltage V₃) is less than the electric potential at the first floating diffusion node FD1. Collectively, this creates an electric potential difference that facilitates transfer of the charge 302 to the transistor capacitor 112.

Because the capacitor transfer transistor 114 is in an OFF state, an electric potential at the capacitor transfer transistor 114 (e.g., the first voltage V₁) is elevated relative to the electric potential at the transistor capacitor 112. This creates a barrier that prevents the charge 302 from moving out of the transistor capacitor 112 to the second floating diffusion node FD2.

Focusing on FIG. 3C, the charge 302 is moved from the transistor capacitor 112 to the second floating diffusion node FD2. The PPD transfer transistor 110 and the transistor capacitor 112 are in OFF states, and the capacitor transfer transistor 114 is in ON states.

Because the transistor capacitor 112 is in an OFF state, an electric potential at the transistor capacitor 112 (e.g., the first voltage V₁) is elevated relative to an electric potential at the second floating diffusion node (e.g., the third voltage V₃). Further, because the capacitor transfer transistor 114 is in an ON state, an electric potential at the capacitor transfer transistor 114 is between the electric potential at the transistor capacitor 112 and an electric potential at the second floating diffusion node FD2. Collectively, this creates an electric potential difference that facilitates transfer of the charge 302 to the second floating diffusion node FD2.

Because the transistor capacitor 112 has a stepped gate dielectric thickness, the transistor capacitor 112 has a stepped electric potential. The stepped electric potential is highest proximate the first floating diffusion node FD1, whereby it creates a barrier preventing the charge 302 from moving to the first floating diffusion node FD1.

As seen in FIGS. 3A-3C, reference is made to the first voltage V₁, the second voltage V₂, and the third voltage V₃. In some embodiments, the first voltage V₁ is or is about 1.9 volts, the second voltage V₂ is or is about 2.2 volts, and the third voltage V₃ is or is about 2.8 volts. Other suitable voltages are, however, amenable in alternative embodiments.

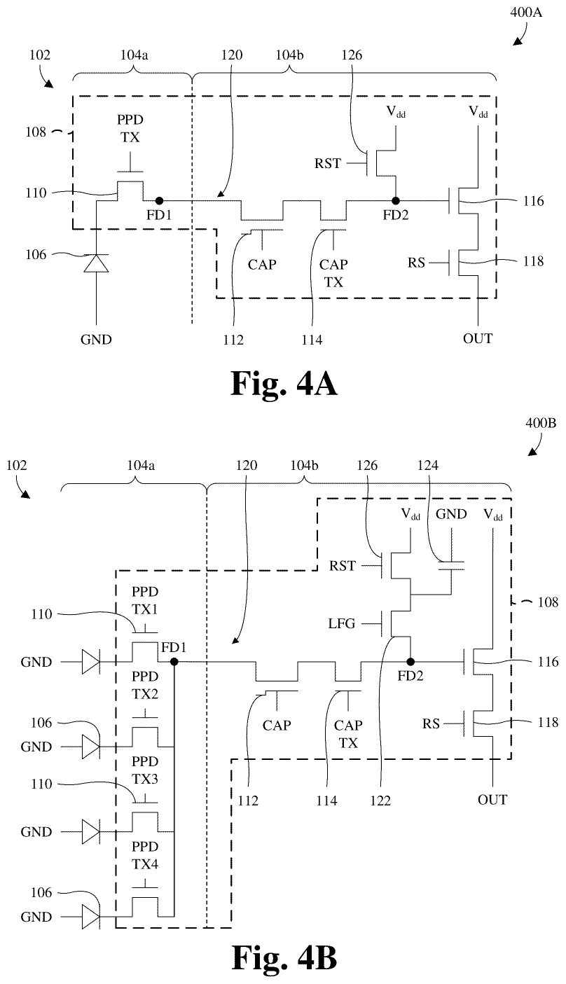

With reference to FIGS. 4A and 4B, circuit diagrams 400A, 400B of some alternative embodiments of the stacked CMOS image sensor of FIG. 1 is provided in which the pixel sensor 102 is varied. In FIG. 4A, the LOFIC transistor 122 and the LOFIC 124 are omitted. As such, the reset transistor 126 is electrically coupled from power V_{dd} to the second floating diffusion node FD2. In FIG. 4B, the pixel sensor 102 comprises a plurality of PPDs 106. For example, the pixel sensor 102 may have two PPDs, four PPDs (as illustrated), eight PPDs, or some other suitable number of PPDs. Further, the pixel sensor 102 comprises a plurality of PPD transfer transistors 110 corresponding to the PPDs 106 with a one-to-one correspondence.

Each of the PPDs 106 is electrically coupled in series with a corresponding one of the PPD transfer transistors 110 from the first floating diffusion node FD1 to ground GND. Further, the PPDs 106 may, for example, individually be their counterpart is described with regard to FIG. 1. The PPD transfer transistors 110 are gated by corresponding PPD transfer signals (e.g., PPD TX1, PPD TX2, PPD TX3, and PPD TX4). Further, the PPD transfer transistors 110 are configured to selectively transfer photo-generated charge to the first floating diffusion node FD1 respectively from the PPDs 106. The PPD transfer transistors 110 may, for example, individually be as their counter is described with regard to FIG. 1.

While FIG. 4B is illustrated with the LOFIC transistor 122 and the LOFIC 124, the LOFIC transistor 122 and the LOFIC 124 may be omitted in alternative embodiments of the stacked CMOS image sensor of FIG. 4B. Further, while the signal timing diagram 200 of FIG. 2 is described with regard to a pixel sensor with a single PPD, it is still applicable to the pixel sensor of FIG. 4B. For example, the PPD transfer signals (e.g., PPD TX1 et al.) in FIG. 4B may individually be as the PPD signal in FIG. 2 is illustrated and described.

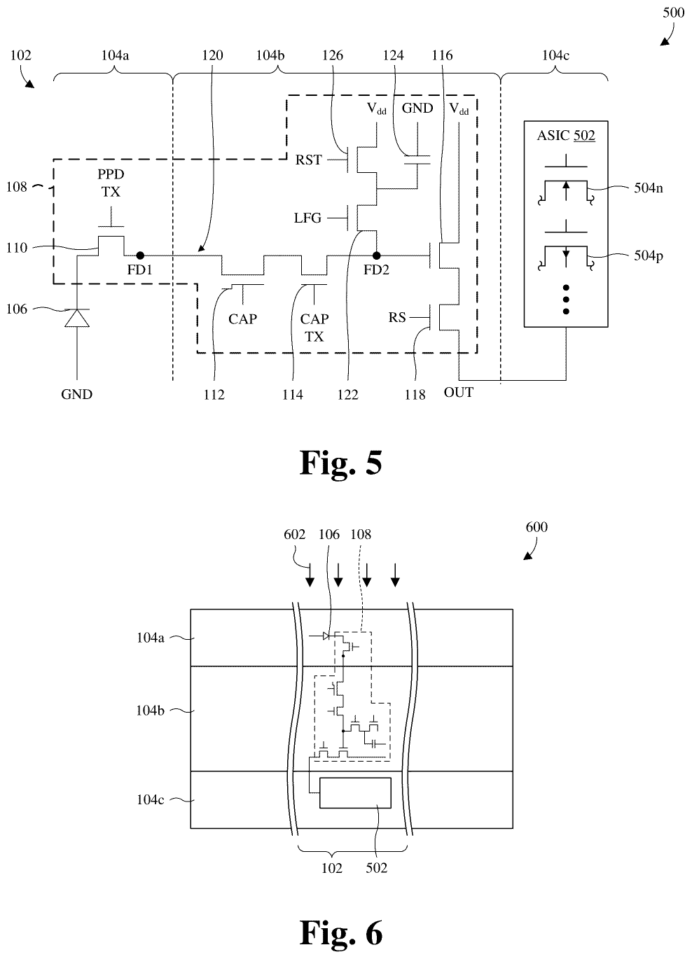

With reference to FIG. 5, a circuit diagram 500 of some embodiments of the stacked CMOS image sensor of FIG. 1 is provided in which the stacked CMOS image sensor further comprises a third IC chip 104c. The third IC chip 104c is bonded to the second IC chip 104b and is separated from the first IC chip 104a by the second IC chip 104b. Further, the third IC chip 104c accommodates an application-specific integrated circuit (ASIC) 502.

The ASIC 502 is electrically coupled to the output OUT of the pixel sensor 102 and any other pixel sensors (not shown) of the stacked CMOS image sensor. Further, the ASIC 502 may, for example, be configured to perform analog-to-digital conversion (ADC), buffering, image processing, the like, or any combination of the foregoing. In some embodiments, the ASIC 502 buffers and performs ADC on the output OUT of the pixel sensor 102 and outputs of any other pixel sensors of the stacked CMOS image sensor to generate digital data representing an image, and then performs imaging processing on the image.

The ASIC 502 is formed in part by a plurality of transistors, including a plurality of n-type transistors 504n (only one of which is shown) and a plurality of p-type transistors 504p (only one of which is shown). Note that the ellipses at the ASIC 502 is used to represent zero or more additional n-type transistors and/or p-type transistors. The n-type transistors 504n and the p-type transistors 504p may, for example, be MOSFETs, FinFETs, GAA FETs, nanosheet field-effect transistors, some other suitable type of transistors, or any combination of the foregoing.

With reference to FIG. 6, a schematic cross-sectional view 600 of some embodiments of the stacked CMOS image sensor of FIG. 5 is provided in which the first, second, and third IC chips 104a-104c are vertically stacked. The first IC chip 104a is at a top of the stacked CMOS image sensor and is configured to receive radiation 602 from a top of the stacked CMOS image sensor. The second IC chip 104b underlies and is bonded to the first IC chip 104a, and the third IC chip 104c underlies and is bonded to the second IC chip 104b.

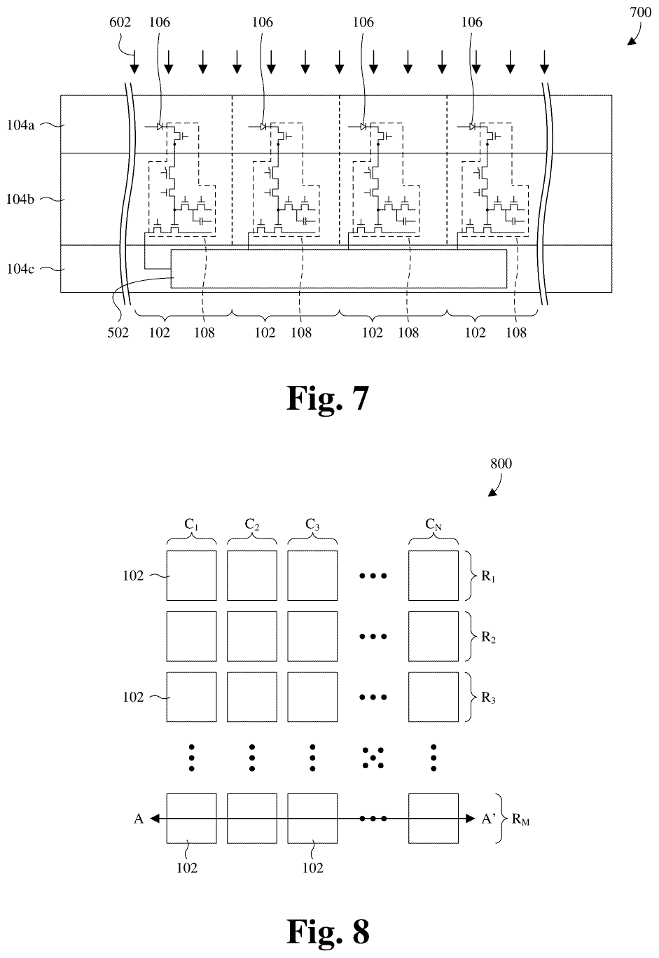

With reference to FIG. 7, a schematic cross-sectional view 700 of some alternative embodiments of the stacked CMOS image sensor of FIG. 5 is provided in which the stacked CMOS image sensor comprises a plurality of pixel sensors 102. The pixel sensors 102 share the ASIC 502 and are each as in FIG. 5. Alternatively, the pixel sensors 102 may each be as in FIG. 4A or 4B. Further, the first, second, third IC chips 104a-104c are vertically stacked as in FIG. 6.

With reference to FIG. 8, a top layout view 800 of some embodiments of the stacked CMOS image sensor of FIG. 7 is provided in which the plurality of pixel sensors 102 are in a plurality of rows and a plurality of columns. The schematic cross-sectional view 700 of FIG. 7 may, for example, be taken along line A-A′ in FIG. 8.

The plurality of rows include rows R₁, R₂, and so on to R_{M}, and the plurality of columns include columns C₁, C₂, and so on to CN. Subscripts of the row labels correspond to row numbers, where M is an integer greater than three. Similarly, subscripts of the column labels correspond to column numbers, where N is an integer greater than three. Further, the plurality of rows and columns form a two-dimensional array in which the pixel sensors 102 are in a periodic, grid pattern. Other suitable patterns are amenable.

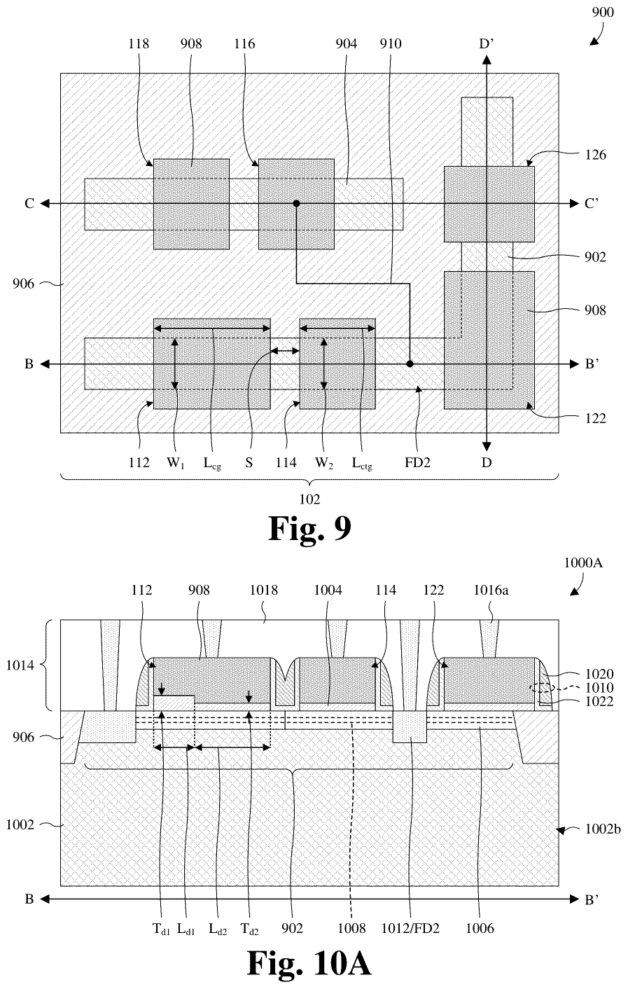

With reference to FIG. 9, a top layout view 900 of some first embodiments of the stacked CMOS image sensor of FIG. 1 is provided at the second IC chip 104b. The transistor capacitor 112, the capacitor transfer transistor 114, the LOFIC transistor 122, and the reset transistor 126 are on a first active semiconductor region 902, and the row-select transistor 118 and the source-follower transistor 116 are on a second active semiconductor region 904. Further, the second floating diffusion node FD2 is in the first active semiconductor region 902, laterally between the capacitor transfer transistor 114 and the LOFIC transistor 122.

The capacitor transfer transistor 114 is electrically coupled to the transistor capacitor 112 and also to the second floating diffusion node FD2 through the first active semiconductor region 902. Similarly, the LOFIC transistor 122 is electrically coupled to the second floating diffusion node FD2 and also to the reset transistor 126 through the first active semiconductor region 902. The row-select transistor 118 is electrically coupled to the source-follower transistor 116 through the second active semiconductor region 904.

The first and second active semiconductor regions 902, 904 are spaced from each other by an isolation structure 906 and are individually surrounded by the isolation structure 906. Further, the first semiconductor active region 902 has an L-shaped top geometry wrapping around a corner of the second active semiconductor region 904. The first active semiconductor region 902 may, for example, have some other suitable top geometry in alternative embodiments. The isolation structure 906 may, for example, be or comprise a shallow trench isolation (STI) structure and/or some other suitable type of isolation structure.

The transistor capacitor 112, the capacitor transfer transistor 114, the LOFIC transistor 122, the reset transistor, and the row-select transistor 118, and the source-follower transistor 116 comprise individual gate electrodes 908. The gate electrodes 908 respectively overlap with the first and second active semiconductor regions 902, 904 and are spaced from each other. Further, the gate electrode of the source-follower transistor 116 is electrically coupled to the second floating diffusion node FD2 by a conductive route 910. The conductive route 910 may, for example, be formed by wires and vias.

In some embodiments, the gate electrode 908 of the transistor capacitor 112 has a length Leg that is about 50-500 nanometers, about 50-275 nanometers, about 275-500 nanometers, or some other suitable value. In some embodiments, the gate electrode 908 of the capacitor transfer transistor 114 has a length L_{etg} of about 50-500 nanometers, about 50-275 nanometers, about 275-500 nanometers, or some other suitable value. In some embodiments, the gate electrode 908 of the transistor capacitor 112 is separated from the gate electrode 908 of the capacitor transfer transistor 114 by a separation S that is about 10-200 nanometers, about 10-105 nanometers, about 105-200 nanometers, or some other suitable value.

In some embodiments, the first active semiconductor region 902 has a first width W₁ at the gate electrode 908 of the transistor capacitor 112 that is about 20-500 nanometers, about 20-260 nanometers, about 260-500 nanometers, or some other suitable value. In some embodiments, the first active semiconductor region 902 has a second width W₂ at the gate electrode 908 of the capacitor transfer transistor 114 that is about 20-500 nanometers, about 20-260 nanometers, about 260-500 nanometers, or some other suitable value.

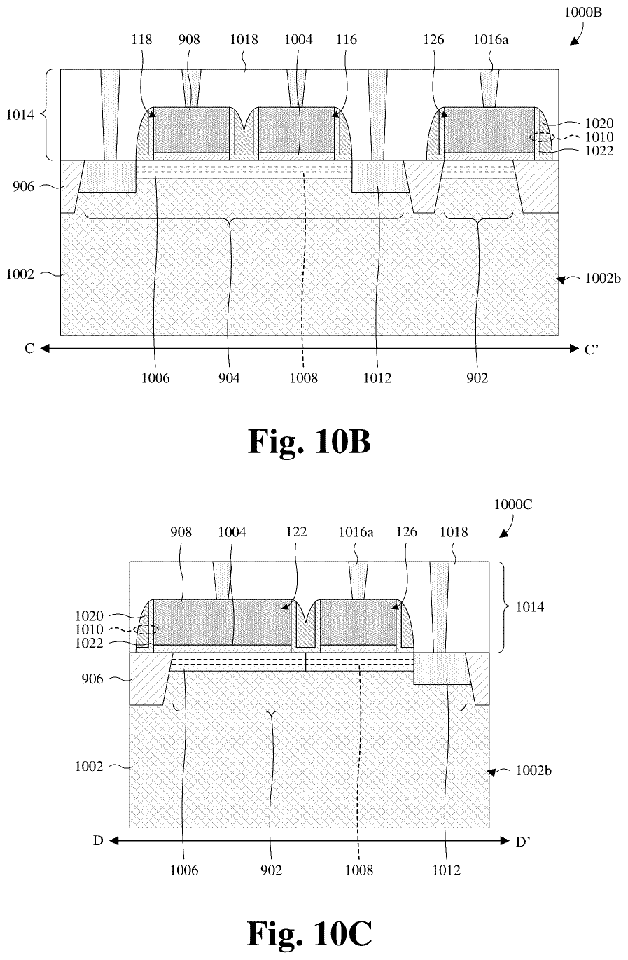

With reference to FIGS. 10A-10C, cross-sectional views 1000A-1000C of some first embodiments of the stacked CMOS image sensor of FIG. 9 are provided. The cross-sectional views 1000A-1000C may respectively be taken along lines B-B′, C-C′, and D-D′ in FIG. 9.

The first and second active semiconductor regions 902, 904 correspond to regions of a semiconductor substrate 1002 and are surrounded and demarcated by the isolation structure 906. Further, the transistor capacitor 112, the capacitor transfer transistor 114, the LOFIC transistor 122, the reset transistor 126, and the row-select transistor 118, and the source-follower transistor 116 (collectively the devices) are on the semiconductor substrate 1002, respectively at the first and second active semiconductor regions 902, 904.

The devices comprise individual gate electrodes 908, individual gate dielectric layers 1004, individual wells 1006, individual channels 1008, corresponding sidewall spacer structures 1010, and corresponding source/drain regions 1012. Note that, as used hereafter, a source/drain region may be a source region or a drain region. Further, the devices underlie and are electrically coupled to an interconnect structure 1014, which comprises a plurality of contact vias 1016a embedded in an interconnect dielectric layer 1018.

The gate electrodes 908 respectively overlie the gate dielectric layers 1004 and border corresponding ones of the source/drain regions 1012. Further, the sidewall spacer structures 1010 are on sidewalls of the gate electrodes 908. The sidewall spacer structures 1010 comprise individual first spacer layers 1020 and individual second spacer layers 1022. In alternative embodiments, the first spacer layers 1020 or the second spacer layers 1022 are omitted. The second spacer layers 1022 wrap around bottom corners of the first spacer layers 1020 to separate the first spacer layers 1020 from the gate electrodes 908 and the semiconductor substrate 1002. The first and second spacer layers 1020, 1022 are dielectric.

The wells 1006 respectively underlie the gate dielectric layers 1004 and extend under the gate dielectric layers 1004 respectively from the source/drain regions 1012. The wells 1006 and the source/drain regions 1012 are in the semiconductor substrate 1002, along a top of the semiconductor substrate 1002. Further, the wells 1006 and the source/drain regions 1012 share a first doping type, but the source/drain regions 1012 have a higher doping concentration than the wells 1006. The first doping type is opposite to a second doping type at a bulk 1002b of the semiconductor substrate 1002. The first doping type may, for example, be n-type, whereas the second doping type may, for example, be p-type, or vice versa.

The wells 1006 of the PPD transfer transistor 110, the transistor capacitor 112, and the capacitor transfer transistor 114 correspond to the electric potentials at these devices in FIGS. 3A-3C. For example, the electric potential at the transistor capacitor 112 in FIGS. 3A-3C is the electric potential at the well 1006 of the transistor capacitor 112. Further, the wells 1006 may have varying doping concentrations to control the electric potentials. Assuming gate voltage, gate dielectric thickness, and so on remain constant, a higher doping concentration may lead to an electric potential at a higher elevation (e.g., closer to ground GND) in FIGS. 3A-3C.

The channels 1008 are buried in the wells 1006 and selectively conductive depending on biasing of corresponding ones of the gate electrodes 908. Burying the channels 1008 in the wells 1006 prevents the channels 1008 from picking up noise at a top surface of the semiconductor substrate 1002 and hence improves imaging performance.

Focusing on FIG. 10A, the capacitor transfer transistor 114 and the LOFIC transistor 122 share one of the source/drain regions 1012, which is also the second floating diffusion node FD2. Further, the transistor capacitor 112 and the capacitor transfer transistor 114 border without an intervening source/drain region and share one of the sidewall spacer structures 1010. Further yet, the gate dielectric layer 1004 of the transistor capacitor 112 has stepped profile stepping down from a first dielectric thickness T_{d1} to a second dielectric thickness T_{d2}.

A portion of the gate dielectric layer 1004 of the transistor capacitor 112 with the first dielectric thickness T_{d1} has a first dielectric length L_{d1}, whereas a portion of the gate dielectric layer 1004 of the transistor capacitor 112 with the second dielectric thickness T_{d2} has a second dielectric length L_{d2}. In some embodiments, a ratio of the first dielectric length L_{d1} to the second dielectric length L_{d2} (e.g., L_{d1}/L_{d2}) is greater than or equal to 0.1 and is less than or equal to 0.5. Other suitable values are, however, amenable in other embodiments.

The first dielectric thickness T_{d1} is on a first side of the transistor capacitor 112 that is electrically coupled to the first floating diffusion node FD1. Note that the first floating diffusion node FD1 is outside the cross-sectional view 1000A of FIG. 10A. The second dielectric thickness T_{d2} is on a second side of the transistor capacitor 112 that is opposite the first side and that is electrically coupled to the capacitor transfer transistor 114. In some embodiments, the first dielectric thickness T_{d1} is about is about 30-100 angstroms, about 30-65 angstroms, about 65-100 angstroms, or some other suitable value. In some embodiments, the second dielectric thickness T_{d2} is about is about 20-100 angstroms, about 20-60 angstroms, about 60-100 angstroms, or some other suitable value. In some embodiments, the gate dielectric layer 1004 of the capacitor transfer transistor 114 has the second dielectric thickness T_{d2}.

As noted above, the electric potential at the transistor capacitor 112 in FIGS. 3A-3C is the electric potential at the well 1006 of the transistor capacitor 112. Further, varying the thickness of the gate dielectric layer 1004 of the transistor capacitor 112 varies the electric potential at the well 1006 of the transistor capacitor 112. Assuming gate voltage, well doping concentration, and so on remain constant, a thicker gate dielectric layer may lead to an electric potential at a higher elevation (e.g., closer ground GND) in FIGS. 3A-3C.

In view of the foregoing, the stepped profile at the gate dielectric layer 1004 of the transistor capacitor 112 leads to a stepped electric potential at the well 1006 of the transistor capacitor 112. Referring concurrently to FIGS. 3A-3C and 10A, the stepped electric potential is at its highest elevation on the first side of the transistor capacitor 112 that is electrically coupled to the first floating diffusion FD1. This creates a barrier preventing the charge 302 from moving back to the first floating diffusion node FD1 during the transfer at FIG. 3C.

Focusing on FIG. 10B, the row-select transistor 118 and the source-follower transistor 116 border without an intervening source/drain region. Further, the row-select transistor 118 and the source-follower transistor 116 share one of the sidewall spacer structures 1010.

Focusing on FIG. 10C, the LOFIC transistor 122 and the reset transistor 126 borders without an intervening source/drain region. Further, the LOFIC transistor 122 and the reset transistor 126 share one of the sidewall spacer structures 1010.

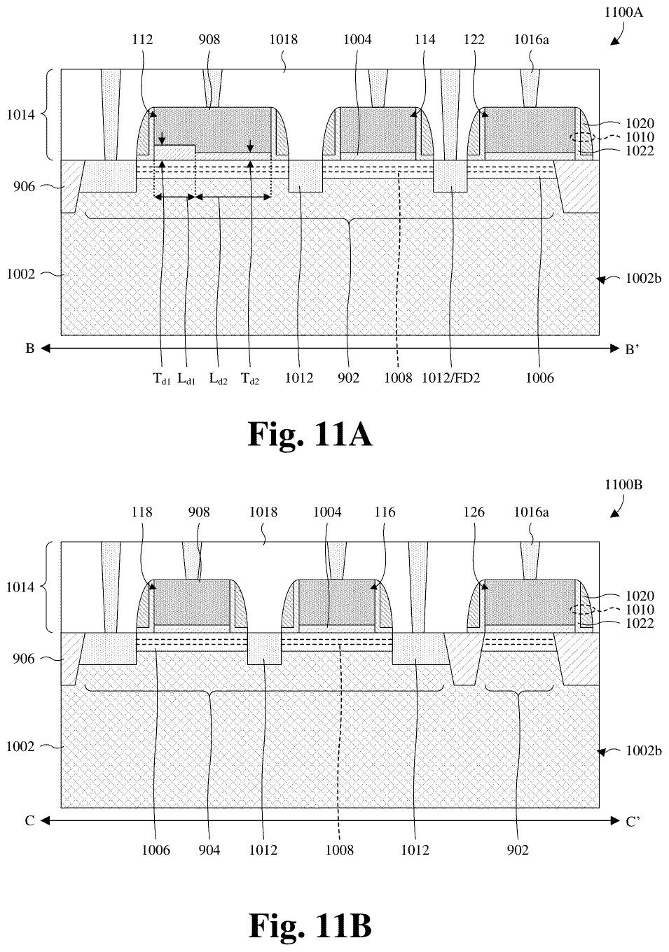

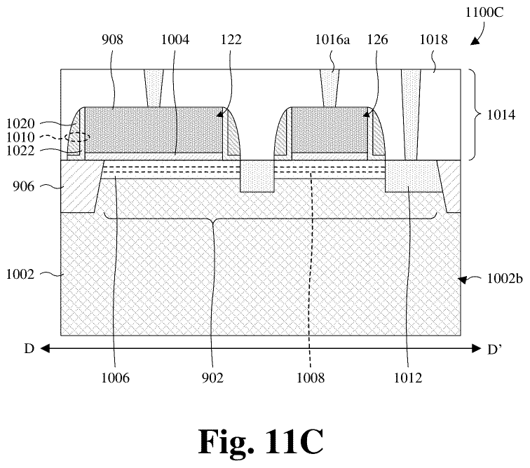

With reference to FIGS. 11A-11C, cross-sectional views 1100A-1100C of some second embodiments of the stacked CMOS image sensor of FIG. 9 are provided. The cross-sectional views 1100A-1100C may respectively be taken along lines B-B′, C-C′, and D-D′ in FIG. 9. In contrast with FIGS. 10A-10C, some of the neighboring devices share source/drain regions and have individual sidewall spacer structures.

Focusing on FIG. 11A, the transistor capacitor 112 and the capacitor transfer transistor 114 border and are separated by one of the source/drain regions 1012. Further, the transistor capacitor 112 and the capacitor transfer transistor 114 have individual ones of the sidewall spacer structures 1010 that are spaced from each other.

Focusing on FIG. 11B, the row-select transistor 118 and the source-follower transistor 116 border and are separated by one of the source/drain regions 1012. Further, the row-select transistor 118 and the source-follower transistor 116 have individual ones of the sidewall spacer structures 1010 that are spaced from each other.

Focusing on FIG. 11C, the LOFIC transistor 122 and the reset transistor 126 border and are separated by one of the source/drain regions 1012. Further, the LOFIC transistor 122 and the reset transistor 126 have individual ones of the sidewall spacer structures 1010 that are spaced from each other.

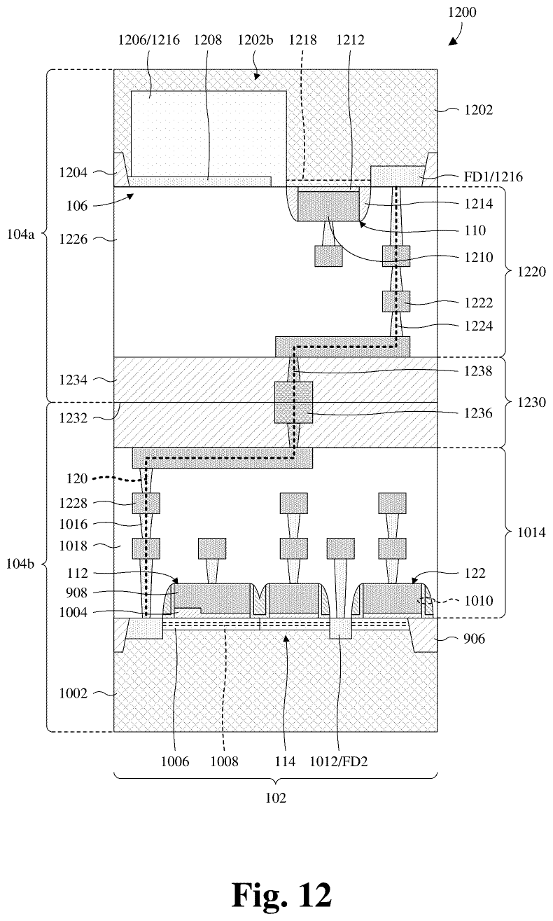

With reference to FIG. 12, a cross-sectional view 1200 of some embodiments of the stacked CMOS image sensor of FIG. 9 at both the first IC chip 104a and the second IC chip 104b is provided. The cross-sectional view 1200 may, for example, be taken along line B-B′ in FIG. 9.

The first IC chip 104a overlies the second IC chip 104b and comprises a first semiconductor substrate 1202. The first semiconductor substrate 1202 accommodates the PPD 106 and the PPD transfer transistor 110. The PPD 106 and the PPD transfer transistor 110 are at least partially formed by the first semiconductor substrate 1202 and are surrounded by an isolation structure 1204. The first semiconductor substrate 1202 may, for example, be a bulk substrate of monocrystalline silicon, silicon germanium, or the like. The isolation structure 1204 may, for example, be an STI structure and/or some other suitable isolation structure.

The PPD 106 comprises a collector region 1206 and a pinning region 1208 underlying the collector region 1206 on a frontside of the first semiconductor substrate 1202. Further, the PPD 106 comprises a portion of a bulk 1202b of the first semiconductor substrate 1202 that adjoins and surrounds the pinning region 1208 and the collector region 1206. During operation, the PPD 106 receives radiation from over the first semiconductor substrate 1202, which results in the accumulation of charge in the collector region 1206. The electric potential at the collector region 1206 corresponds to the electric potential at the PPD 106 in FIGS. 3A-3C.

The bulk 1202b of the first semiconductor substrate 1202 and the pinning region 1208 correspond to doped regions of the first semiconductor substrate 1202 and share a first doping type. Further, the pinning region 1208 has a higher doping concentration than the bulk 1202b of the first semiconductor substrate 1202. The collector region 1206 corresponds to a doped region of the first semiconductor substrate 1202 and has a second doping type opposite to the first doping type. For example, the first doping type may be p-type, whereas the second doping type may be n-type, or vice versa. Further, the collector region 1206 adjoins the pinning region 1208 and the bulk 1202b of the first semiconductor substrate 1202 to form a PN junction.

The PPD transfer transistor 110 borders the PPD 106 on the frontside of the first semiconductor substrate 1202. Further, the PPD transfer transistor 110 comprises a gate electrode 1210, a gate dielectric layer 1212, a sidewall spacer structure 1214, a pair of source/drain regions 1216, and a channel 1218. The gate electrode 1210 and the gate dielectric layer 1212 are stacked with the gate dielectric layer 1212 separating the gate electrode 1210 from the first semiconductor substrate 1202. The sidewall spacer structure 1214 is on sidewalls of the gate electrode 1210 and the gate dielectric layer 1212.

The source/drain regions 1216 are in the first semiconductor substrate 1202 and are separated from each other by the channel 1218 in the first semiconductor substrate 1202. Further, the source/drain regions 1216 correspond to doped regions of the first semiconductor substrate 1202 sharing a common doping type, which is opposite to that of the bulk 1202b of the first semiconductor substrate 1202. For example, the source/drain regions 1216 may be n-type, and the bulk 1202b of the first semiconductor substrate 1202 may be p-type, or vice versa. One of the source/drain regions 1216 is formed by the collector region 1206, and the other one of the source/drain regions 1216 forms the first floating diffusion node FD1.

A first interconnect structure 1220 underlies and is electrically coupled to the PPD transfer transistor 110. The first interconnect structure 1220 comprise a plurality of wires 1222 and a plurality of vias 1224 stacked in an interconnect dielectric layer 1226. The wires 1222 and the vias 1224 are grouped respectively into a plurality of wire levels and a plurality of via levels that are alternatingly stacked to form conductive paths.

The second IC chip 104b underlies the first IC chip 104a and comprises a second semiconductor substrate 1002 that accommodates a plurality of devices. The devices include the transistor capacitor 112, the capacitor transfer transistor 114, and the LOFIC transistor 122. Further, the devices may include the source-follower transistor 116, the row-select transistor 118, and the reset transistor 126 outside the cross-sectional view 1200 of FIG. 12. The devices are at least partially formed by the second semiconductor substrate 1002 and are surrounded by an isolation structure 906. Further, the devices may, for example, be as in FIGS. 9 and 10A-10C or as in FIGS. 9 and 11A-11C. The second semiconductor substrate 1002 may, for example, be a bulk substrate of monocrystalline silicon, silicon germanium, or the like.

A second interconnect structure 1014 overlies and is electrically coupled to the devices. The second interconnect structure 1014 comprise a plurality of wires 1228 and a plurality of vias 1016 stacked in an interconnect dielectric layer 1018. The wires 1228 and the vias 1016 are grouped respectively into a plurality of wire levels and a plurality of via levels that are alternatingly stacked to form conductive paths. For example, the second interconnect structure 1014 may form the conductive route 910 of FIG. 9. Further, the vias at a via level closest to the second semiconductor substrate 1002 may also be regarded as contact vias. In some embodiments, the LOFIC 124 seen in FIG. 1 is in and electrically coupled to the second interconnect structure 1014, outside the cross-sectional view 1200 of FIG. 12.

A bond structure 1230 is between the first and second IC chips 104a, 104b and facilitates bonding of the first and second IC chips 104a, 104b together at a bond interface 1232. Such bonding may, for example, include a combination of metal-to-metal bonding and dielectric-to-dielectric bonding at the bond interface 1232.

The bond structure 1230 comprises bond dielectric layers 1234 individual to the first and second IC chips 104a, 104b and directly contacting and bonded together at the bond interface 1232. Further, the bond structure 1230 comprises bond pads 1236 individual to the first and second IC chips 104a, 104b and directly contacting and bonded together at the bond interface 1232. The bond pads 1236 are inset respectively into the bond dielectric layers 1234 and are electrically coupled respectively to the first and second interconnect structures 1220, 1014 by bond vias 1238 respectively in the bond dielectric layers 1234.

As above, the transistor capacitor 112 and the capacitor transfer transistor 114 isolate the second floating diffusion FD2 from parasitic capacitance at the first floating diffusion node FD1 and a long conductive path 120 extending from the first floating diffusion node FD1 to the transistor capacitor 112. This long conductive path 120 is formed by the bond structure 1230, the first interconnect structure 1220, and the second interconnect structure 1014.

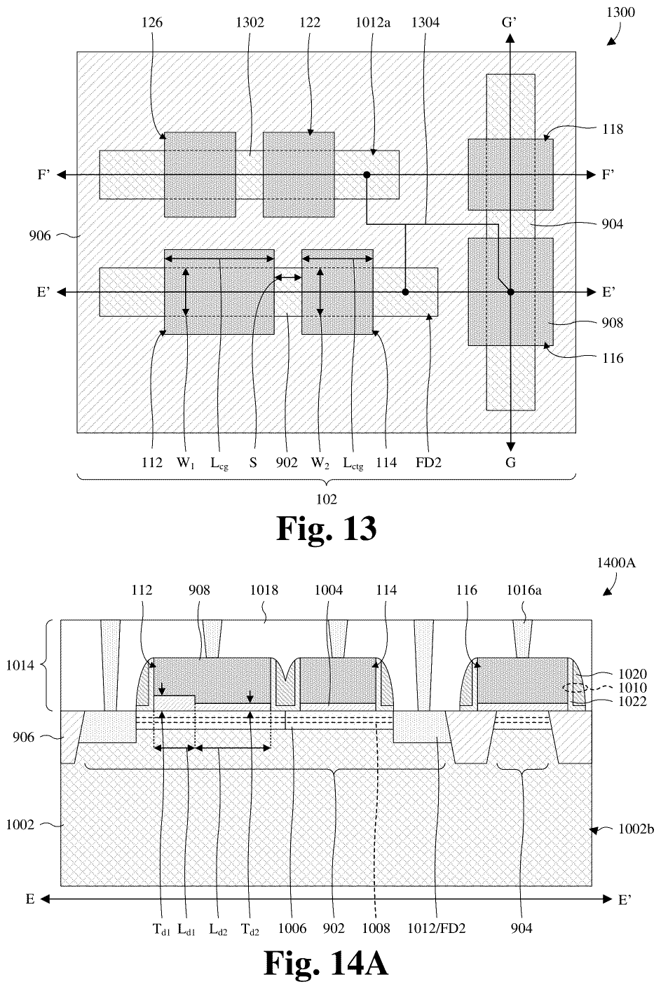

With reference to FIG. 13, a top layout view 1300 of some second embodiments of the stacked CMOS image sensor of FIG. 1 is provided at the second IC chip 104b. In contrast with FIG. 9, the reset transistor 126 and the LOFIC transistor 122 are on a third active semiconductor region 1302, which is spaced from the first and second active semiconductor regions 902, 904. Further, the second active semiconductor region 904 has shifted to where the reset transistor 126 and the LOFIC transistor 122 were in FIG. 9.

A conductive route 1304 extends from the gate electrode 908 of the source-follower transistor 116 to electrically couple the gate electrode 908 to the second floating diffusion node FD2 and further to a source/drain region 1012a of the LOFIC transistor 122. The conductive route 1304 may, for example, be formed by wires and vias.

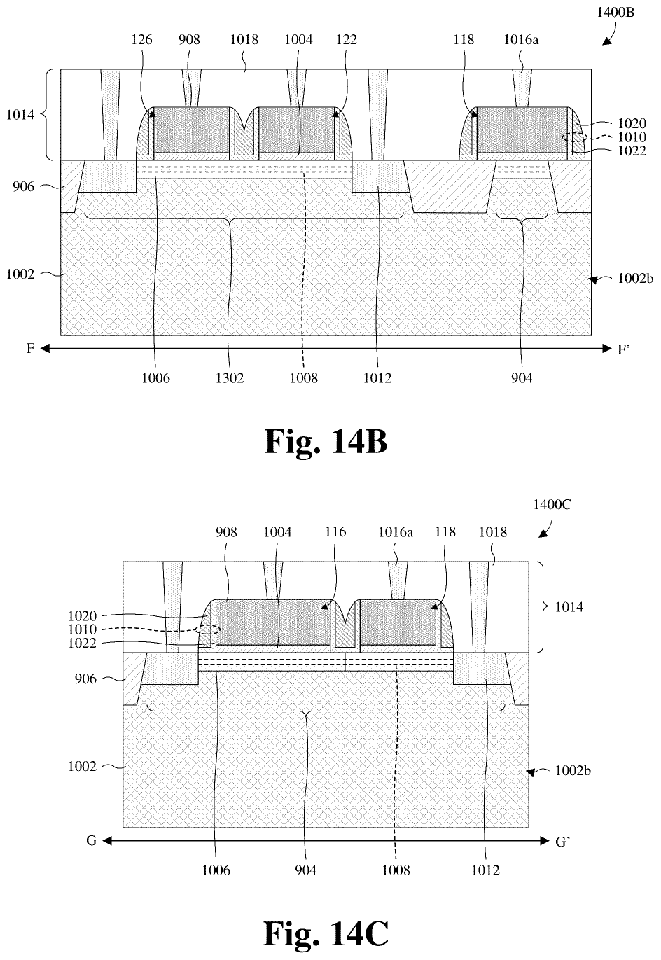

With reference to FIGS. 14A-14C, cross-sectional views 1400A-1400C of some first embodiments of the stacked CMOS image sensor of FIG. 13 are provided. The cross-sectional views 1400A-1400C may be taken respectively along lines E-E′, F-F′, and G-G′ in FIG. 13. Further, the cross-sectional views 1400A-1400C may, for example, respectively be as the cross-sectional views 1000A-1000C of FIGS. 10A-10C are described, except for the change in layout seen by comparison of FIG. 13 to FIG. 9.

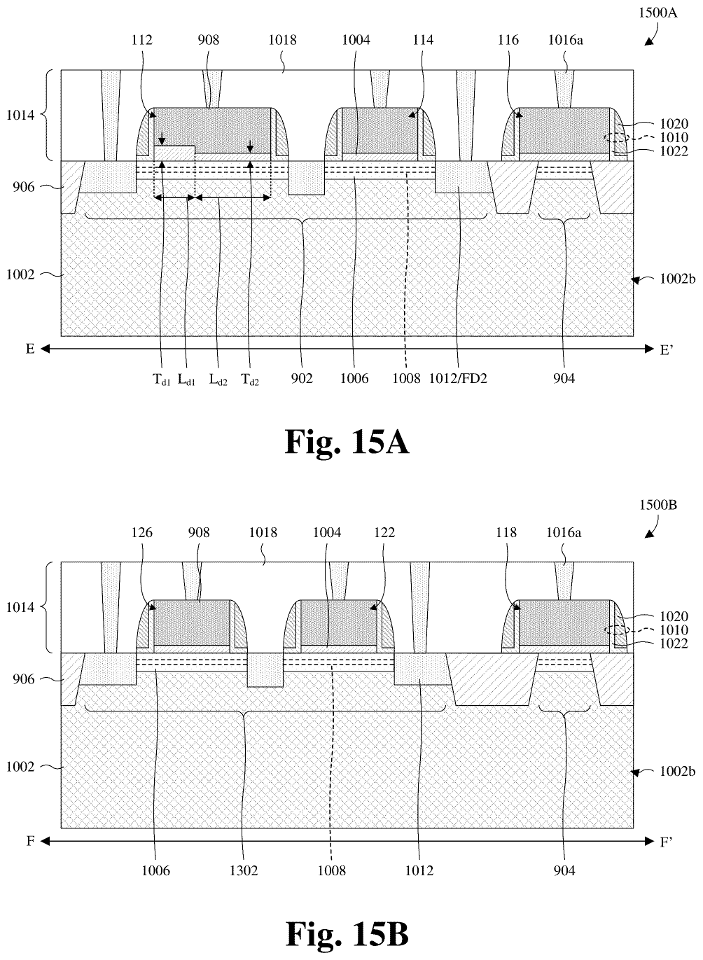

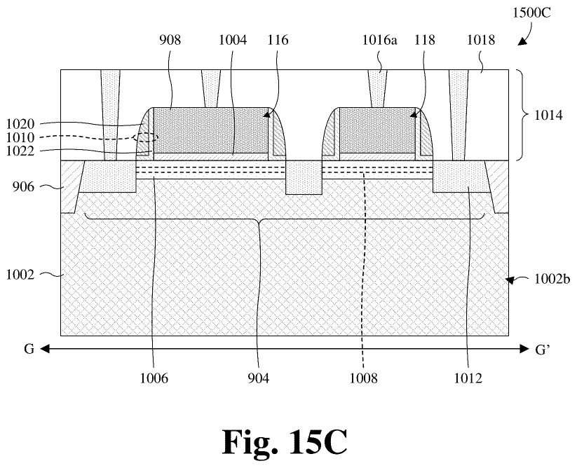

With reference to FIGS. 15A-15C, cross-sectional views 1500A-1500C of some second embodiments of the stacked CMOS image sensor of FIG. 13 are provided. The cross-sectional views 1500A-1500C may respectively be taken along lines E-E′, F-F′, and G-G′ in FIG. 13. In contrast with FIGS. 14A-14C, some of the neighboring devices share source/drain regions and have individual sidewall spacer structures.

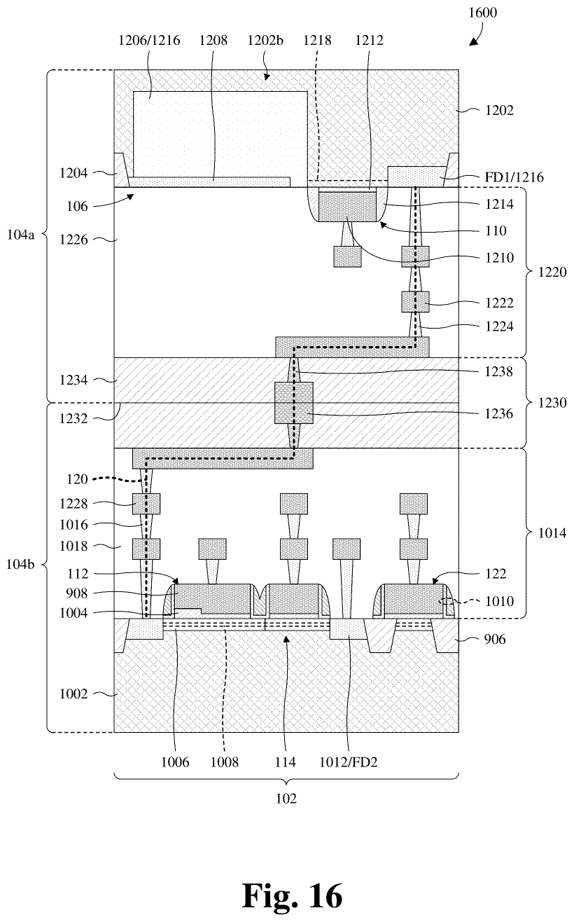

With reference to FIG. 16, a cross-sectional view 1600 of some embodiments of the stacked CMOS image sensor of FIG. 13 at both the first IC chip 104a and the second IC chip 104b is provided. The cross-sectional view 1600 may, for example, be taken along line E-E′ in FIG. 13 and/or may, for example, be as the cross-sectional view 1200 of FIG. 12 is described, except for the change in layout seen by comparison of FIG. 13 to FIG. 9.

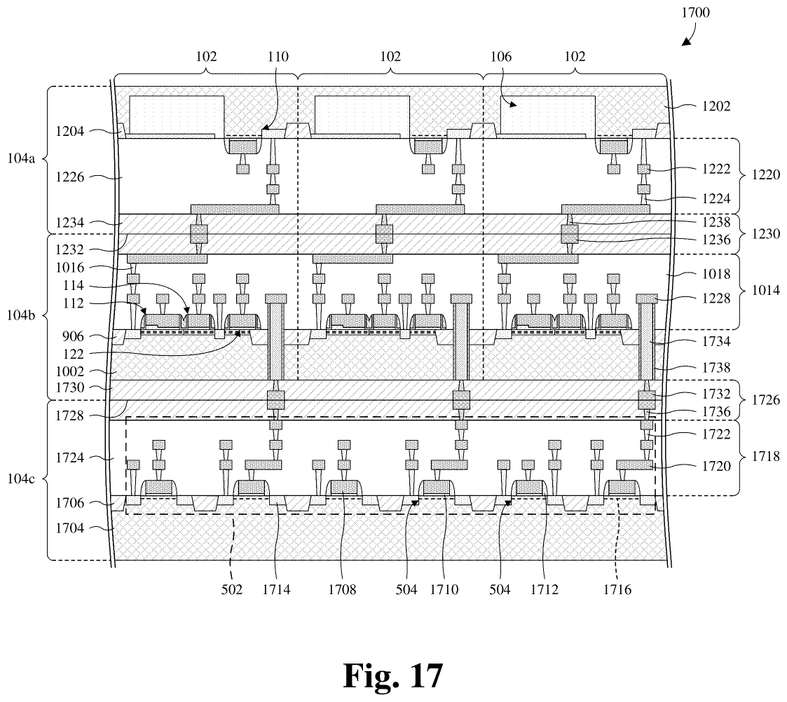

With reference to FIG. 17, a cross-sectional view 1700 of some embodiments of a stacked CMOS image sensor is provided in which the stacked CMOS image sensor comprises a plurality of pixel sensors 102, each as in FIG. 12, and further comprises a third IC chip 104c with an ASIC 502. The third IC chip 104c underlies the second IC chip 104b and comprises a plurality of transistors 504 at least partially formed by a third semiconductor substrate 1704 of the third IC chip 104c. The third semiconductor substrate 1704 may, for example, be a bulk substrate of monocrystalline silicon, silicon germanium, or the like.

The transistors 504 are on a frontside of the third semiconductor substrate 1704 and are further laterally separated from each other by an isolation structure 1706. The isolation structure 1706 may, for example, be or comprise a STI structure or some other suitable isolation structure. Further, the transistors 504 comprise individual gate electrodes 1708, individual gate dielectric layers 1710, individual sidewall spacer structures 1712, individual pairs of source/drain regions 1714, and individual channels 1716.

The gate electrodes 1708 are stacked respectively with the gate dielectric layers 1710, which separate the gate electrodes 1708 from the third semiconductor substrate 1704. The sidewall spacer structures 1712 are dielectric and are respectively on sidewalls of the gate electrodes 1708. The pairs of source/drain regions 1714 are in the third semiconductor substrate 1704. Further, the source/drain regions of each pair of source/drain regions 1714 are separated by a corresponding one of the channels 1716.

A third interconnect structure 1718 overlies and is electrically coupled to the transistors 504. The third interconnect structure 1718 comprise a plurality of wires 1720 and a plurality of vias 1722 stacked in an interconnect dielectric layer 1724. The wires 1720 and the vias 1722 are grouped respectively into a plurality of wire levels and a plurality of via levels that are alternatingly stacked to form conductive paths leading from the transistors 504.

An additional bond structure 1726 is between the third interconnect structure 1718 and the second semiconductor substrate 1002. Further, the additional bond structure 1726 facilitates bonding of the second and third IC chips 104b, 104c together at an additional bond interface 1728. Such bonding may, for example, include a combination of metal-to-metal bonding and dielectric-to-dielectric bonding at the additional bond interface 1728.

The additional bond structure 1726 comprises additional bond dielectric layers 1730 individual to the second and third IC chips 104b, 104c and directly contacting and bonded together at the additional bond interface 1728. Further, the additional bond structure 1726 comprises additional bond pads 1732 individual to the second and third IC chips 104b, 104c and directly contacting and bonded together at the additional bond interface 1728. The additional bond pads 1732 are inset respectively into the additional bond dielectric layers 1730 and are electrically coupled respectively to the third interconnect structure 1718 and a plurality of TSVs 1734 by additional bond vias 1736 respectively in the additional bond dielectric layers 1730.

The TSVs 1734 are individual to the pixel sensors 102 and extend through the second semiconductor substrate 1002, from the second interconnect structure 1014 to the additional bond structure 1726. Further, the TSVs 1734 are separated from the second semiconductor substrate 1002 by individual TSV dielectric layers 1738.

The transistors 504 and the third interconnect structure 1718 form an ASIC 502 electrically coupled to the pixel sensors 102 through the additional bond structure 1726 and the TSVs 1734. The ASIC 502 may, for example, be as described with regard to FIGS. 5, 6, and 7, whereby the transistors 504 may, for example, correspond to the n-type transistors 504n and the p-type transistors 504p in FIG. 5. Further, the ASIC 502 may, for example, be configured to perform ADC, buffering, image processing, the like, or any combination of the foregoing.

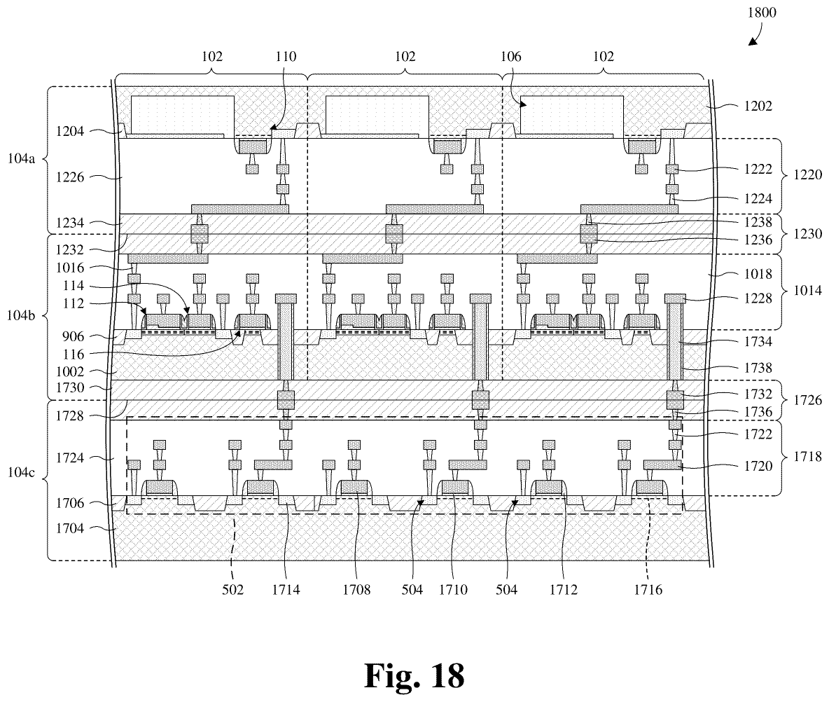

With reference to FIG. 18, a cross-sectional view 1800 of some alternative embodiments of the stacked CMOS image sensor of FIG. 17 is provided in which the pixel sensors 102 are each as in FIG. 16.

While FIGS. 12 and 17 illustrate pixel-sensor embodiments as in FIG. 10A, pixel-sensor embodiments as in FIG. 11A and/or any other figure herein are amenable. Further, while FIGS. 16 and 18 illustrate pixel-sensor embodiments as in FIG. 14A, pixel-sensor embodiments as in FIG. 15A and/or any other figure herein are amenable.

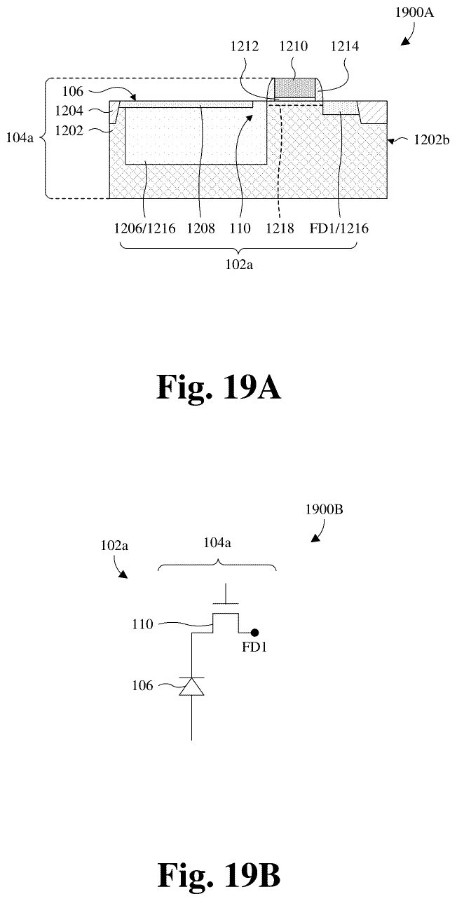

With reference to FIGS. 19A through 35B, a series of views of some embodiments of a method for forming a stacked CMOS image sensor comprising a pixel sensor for HCG is provided. The method may, for example, be performed to form the stacked CMOS image sensor as in FIG. 17 or some other suitable stacked CMOS image sensor.

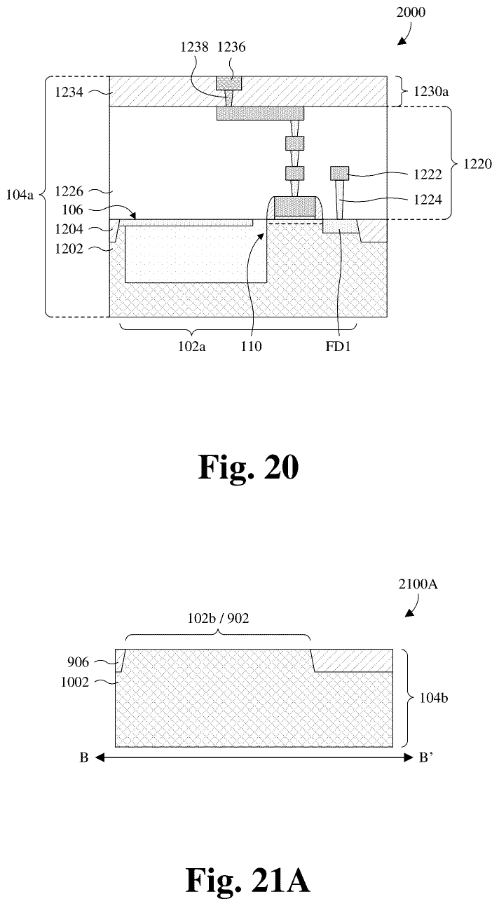

As illustrated by the views of FIGS. 19A, 19B, and 20, a first IC chip 104a comprising a first pixel portion 102a of a pixel sensor is formed.

Focusing on a cross-sectional view 1900A of FIG. 19A, and a circuit diagram 1900B of FIG. 19B, an isolation structure 1204 is formed surrounding and demarcating the first pixel portion 102a in a first semiconductor substrate 1202. The isolation structure 1204 may, for example, be or comprise a STI structure and/or the like. Further, a PPD 106, a first floating diffusion node FD1, and a PPD transfer transistor 110 are formed.

The PPD 106 and the first floating diffusion node FD1 are formed in the first semiconductor substrate 1202. Further, the PPD 106 and the first floating diffusion node FD1 are formed laterally separated from each other. The PPD 106 comprises a collector region 1206 and a pinning region 1208 overlying the collector region 1206, and further comprises a portion of a bulk 1202b of the first semiconductor substrate 1202. The bulk 1202b of the first semiconductor substrate 1202 forms or is otherwise electrically coupled to an anode of the PPD 106, and the collector region 1206 forms a cathode of the PPD 106.

The collector region 1206, the pinning region 1208, and the first floating diffusion node FD1 correspond to doped regions of the first semiconductor substrate 1202. The collector region 1206 and the first floating diffusion node FD1 share a first doping type, and the pinning region 1208 and the bulk 1202b of the first semiconductor substrate 1202 share a second doping type opposite the first doping type. For example, the first doping type may be n-type, whereas the second doping type may be p-type, or vice versa. Further, the pinning region 1208 and the bulk 1202b of the first semiconductor substrate 1202 surround the collector region 1206 and the first floating diffusion node FD, such that boundaries of the collector region 1206 and the first floating diffusion node FD are demarcated by PN junctions.

The PPD transfer transistor 110 comprises a gate electrode 1210, a gate dielectric layer 1212, a sidewall spacer structure 1214, a pair of source/drain regions 1216, and a channel 1218. The gate electrode 1210 and the gate dielectric layer 1212 are vertically stacked on the first semiconductor substrate 1202, and the sidewall spacer structure 1214 is on sidewalls of the gate electrode 1210 and the gate dielectric layer 1212. The source/drain regions 1216 are in the first semiconductor substrate 1202 and are separated from each other by the channel 1218 in the first semiconductor substrate 1202. Further, the source/drain regions 1216 correspond to the collector region 1206 and the first floating diffusion node FD1.

Focusing on a cross-sectional view 2000 of FIG. 20, a first interconnect structure 1220 and a first bond substructure 1230a are formed.

The first interconnect structure 1220 is formed over and electrically coupled to the PPD transfer transistor 110 and the first floating diffusion node FD1. The first interconnect structure 1220 comprises a plurality of wires 1222 and a plurality of vias 1224 in an interconnect dielectric layer 1226. The wires 1222 and the vias 1224 are conductive and grouped respectively into a plurality of wire levels and a plurality of via levels that are alternatingly stacked.

The first bond substructure 1230a is formed over and electrically coupled to the first interconnect structure 1220. The first bond substructure 1230a comprises a bond pad 1236 and a bond via 1238 in a bond dielectric layer 1234. The bond pad 1236 and the bond dielectric layer 1234 form a common bond surface facing away from the first interconnect structure 1220, and the bond via 1238 extends from the bond pad 1236 to the first interconnect structure 1220.

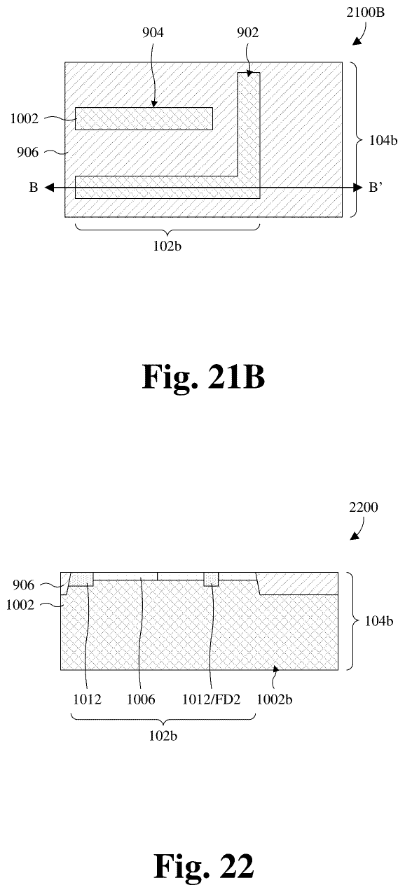

As illustrated by the views of FIGS. 21A, 21B, 22-26, 27A, 27B, 28, 29A, and 29B, a second IC chip 104b comprising a second pixel portion 102b of the pixel sensor is formed. The second pixel portion 102b may, for example, be as in FIGS. 9 and 10A-10C, as in FIGS. 9 and 11A-11C, as in FIGS. 13 and 14A-14C, or as in FIGS. 13 and 15A-15C.

Focusing on a cross-sectional view 2100A of FIG. 21A, and a top layout view 2100B of FIG. 21B, an isolation structure 906 is formed. The cross-sectional view 2100A may, for example, be taken along line B-B′ in the top layout view 2100B. The isolation structure 906 surrounds and demarcates a first active semiconductor region 902 and a second active semiconductor region 904. The first active semiconductor region 902 has an L-shaped top geometry and wraps around a corner of the second active semiconductor region 904. The isolation structure 906 may, for example, be or comprise a STI structure and/or the like.

Focusing on a cross-sectional view 2200 of FIG. 22, a plurality of wells 1006 and a plurality of source/drain regions 1012 are formed in the second semiconductor substrate 1002 by selective doping of the second semiconductor substrate 1002. The plurality of wells 1006 may be formed by a first selective doping process, and then the plurality of source/drain regions 1012 may be formed by a second selective doping process, or vice versa. A selective doping process may, for example, comprise ion implantation with a mask (e.g., of photoresist or the like) in place or some other suitable type of selective doping process.

The wells 1006 and the source/drain regions 1012 correspond to readout devices being formed, which include, among other things, a transistor capacitor, a capacitor transfer transistor, and a LOFIC transistor 122. The wells 1006 and the source/drain regions 1012 are arranged along a top surface of the second semiconductor substrate 1002 and share a doping type, which is opposite a doping type at a bulk 1002b of the second semiconductor substrate 1002. For example, the doping type may be n-type, whereas the opposite doping type may be p-type, or vice versa. Further, the source/drain regions 1012 have a greater doping concentration than the wells 1006, and a source/drain region corresponding to the capacitor transfer transistor may be regarded as a second floating diffusion node FD2.

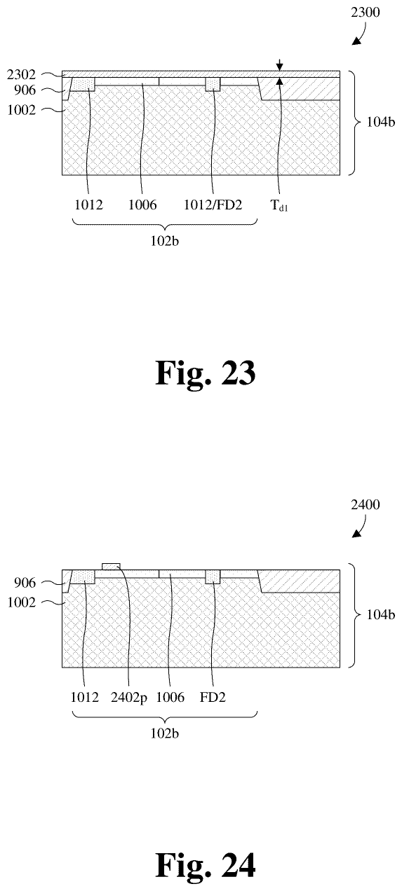

Focusing on a cross-sectional view 2300 of FIG. 23, a first dielectric layer 2302 is deposited overlying the second semiconductor substrate 1002. The first dielectric layer 2302 has a first dielectric thickness T_{d1} and may, for example, be or comprise silicon oxide and/or the like.

Focusing on a cross-sectional view 2400 of FIG. 24, the first dielectric layer 2302 is patterned to form a dielectric structure 2402p individual to and overlying one of the wells 1006. As seen hereafter, this well corresponds to a transistor capacitor being formed. The patterning further exposes portions of the second semiconductor substrate 1002 that are uncovered by the dielectric structure 2402p. The patterning may for example, be performed by a photolithography/etching process or by some other suitable patterning process.

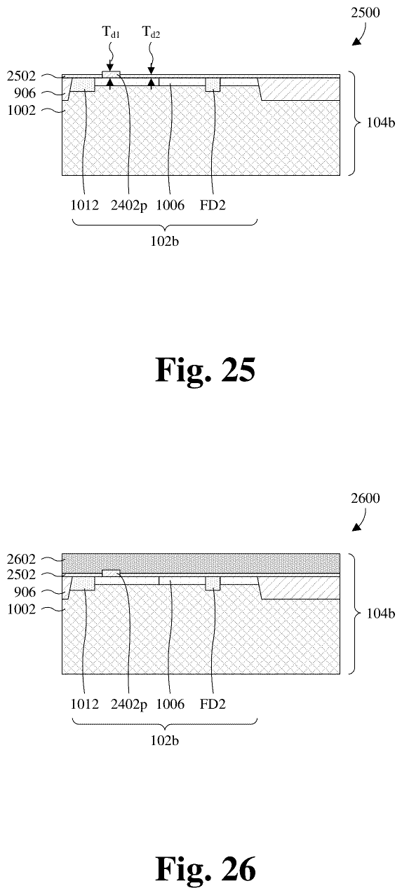

Focusing on a cross-sectional view 2500 of FIG. 25, a second dielectric layer 2502 is deposited overlying the second semiconductor substrate 1002. The second dielectric layer 2502 has a second dielectric thickness T_{d2}, which is less than the first dielectric thickness T_{d1}. The second dielectric layer 2502 may, for example, be or comprise silicon oxide and/or the like. In some embodiments, the second dielectric layer 2502 is a same material as the dielectric structure 2402p. Further, the second dielectric layer 2502 is deposited by thermal oxidation or the like so the second dielectric layer 2502 minimally deposits on the dielectric structure 2402p.

Focusing on a cross-sectional view 2600 of FIG. 26, a conductive layer 2602 is deposited overlying the second dielectric layer 2502 and the dielectric structure 2402p. In some embodiments, a planarization is further performed to flatten a top surface of the conductive layer 2602. The planarization may, for example, be performed by a chemical mechanical polish (CMP) and/or by some other suitable planarization process.

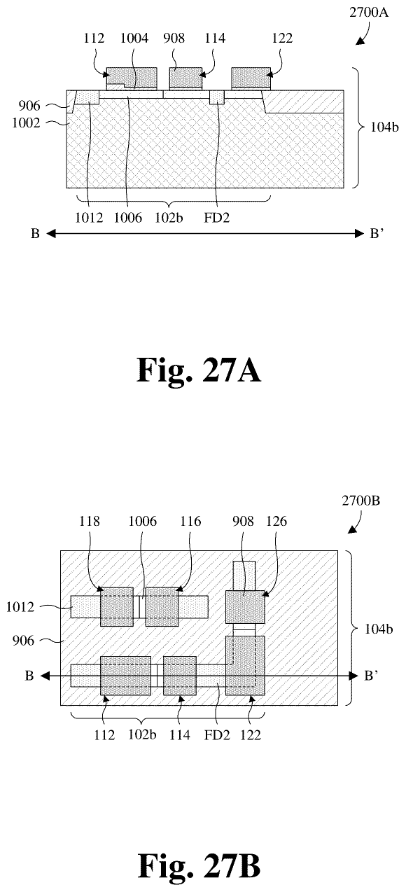

Focusing on a cross-sectional view 2700A of FIG. 27A, and a top layout view 2700B of FIG. 27B, the conductive layer 2602, the second dielectric layer 2502, and the dielectric structure 2402p are patterned together. The cross-sectional view 2700A may, for example, be taken along line B-B′ in the top layout view 2700B.

The patterning forms a plurality of readout devices, including a transistor capacitor 112, a capacitor transfer transistor 114, a source-follower transistor 116, a row-select transistor 118, a LOFIC transistor 122, and a reset transistor 126. Further, the patterning forms a plurality of gate electrodes 908 and a plurality of gate dielectric layers 1004 that are individual to and that form gate stacks of the readout devices. The patterning may, for example, be performed by a photolithography/etching process or by some other suitable patterning process.

The gate electrodes 908 are formed from the conductive layer 2602 and respectively overlie the gate dielectric layers 1004. The gate dielectric layers 1004 are formed from the second dielectric layer 2502, and the gate dielectric layer 1004 of the transistor capacitor 112 is further formed from the dielectric structure 2402p. Further, the gate dielectric layers 1004 respectively overlie the wells 1006, which are individual to the readout devices.

Because the gate dielectric layer 1004 of the transistor capacitor 112 is formed from both the dielectric structure 2402p and the second dielectric layer 2502, the gate dielectric layer 1004 of the transistor capacitor 112 has a stepped profile. Further, the gate electrode 908 of the transistor capacitor 112 has a stepped bottom profile. The stepped profile at the gate dielectric layer 1004 of the transistor capacitor 112 creates an electric potential with a stepped profile at the well 1006 of the transistor capacitor 112. As described above, this creates a barrier that prevents charge from flowing from the transistor capacitor 112 to the first floating diffusion node FD1.

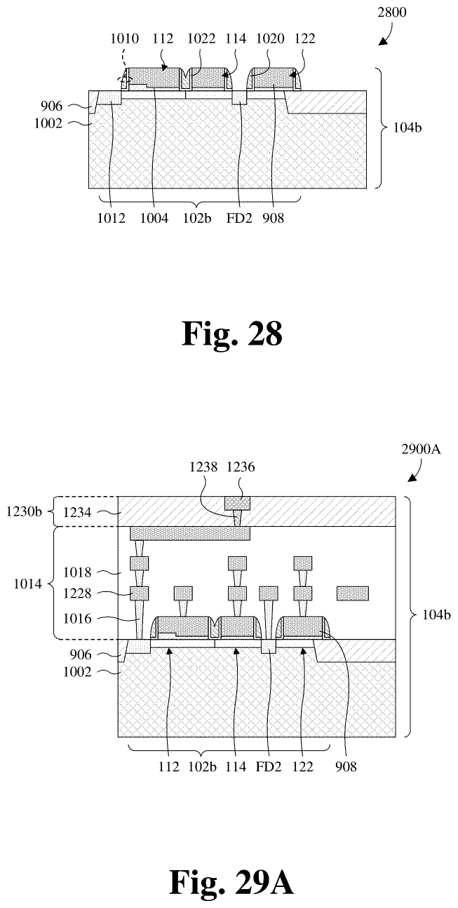

Focusing on a cross-sectional view 2800 of FIG. 28, a plurality of sidewall spacer structures 1010 are formed respectively on sidewalls of the gate electrodes 908. The sidewall spacer structures 1010 comprise individual first spacer layers 1020 and individual second spacer layers 1022. In alternative embodiments, the first spacer layers 1020 or the second spacer layers 1022 are omitted. The second spacer layers 1022 wrap around bottom corners of the first spacer layers 1020 to separate the first spacer layers 1020 from the gate electrodes 908 and the semiconductor substrate 1002. The first and second spacer layers 1020, 1022 are dielectric.

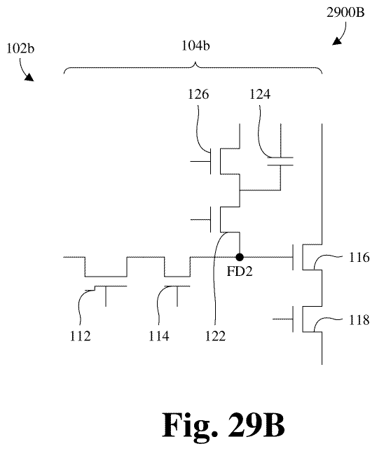

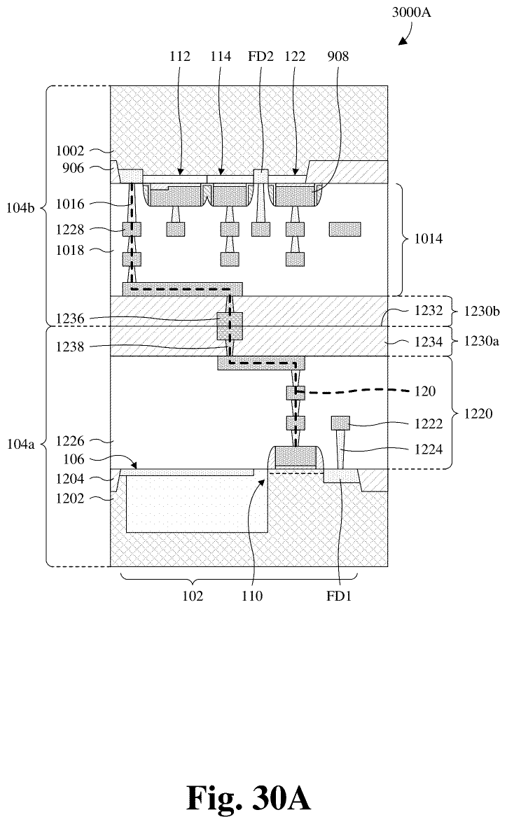

Focusing on a cross-sectional view 2900A of FIG. 29A, and a circuit diagram 2900B of FIG. 29B, a second interconnect structure 1014 and a LOFIC 124 are formed. The second interconnect structure 1014 is formed over and electrically coupled to the readout devices (e.g., the transistor capacitor 112, the capacitor transfer transistor 114, etc.) on the second semiconductor substrate 1002. Further, the LOFIC 124 is formed in and electrically coupled to the second interconnect structure 1014 while the second interconnect structure 1014 is formed. Note that the LOFIC 124 is outside the cross-sectional view 2900A.

The second interconnect structure 1014 comprises a plurality of wires 1228 and a plurality of vias 1016 in an interconnect dielectric layer 1018. The wires 1228 and the vias 1016 are conductive and are grouped respectively into a plurality of wire levels and a plurality of via levels that are alternatingly stacked to form conductive paths interconnecting the readout devices and the LOFIC 124 as in FIG. 29B. For example, such conductive paths include a conductive path electrically coupling the second floating diffusion node FD2 to the source-follower transistor 116 (see FIG. 27B) outside the cross-sectional view 2900A.

In addition to the second interconnect structure 1014 and the LOFIC 124, a second bond substructure 1230b is formed over and electrically coupled to the second interconnect structure 1014. The second bond substructure 1230b comprises a bond pad 1236 and a bond via 1238 in a bond dielectric layer 1234. The bond pad 1236 and the bond dielectric layer 1234 form a common bond surface facing away from the second interconnect structure 1014, and the bond via 1238 extends from the bond pad 1236 to the second interconnect structure 1014.

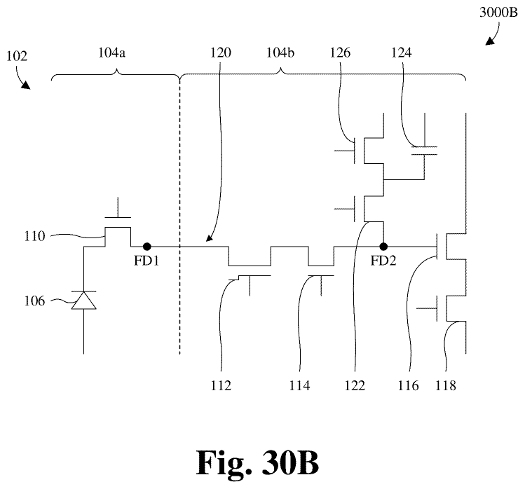

As illustrated by a cross-sectional view 3000A of FIG. 30A, and a circuit diagram 3000B of FIG. 30B, the second IC chip 104b of FIGS. 29A and 29B is vertically flipped and is bonded to the first IC chip 104a of FIG. 20 at a first bond interface 1232. The bonding comprises both metal-to-metal bonding and dielectric-to-dielectric bonding. The bonding forms a pixel sensor 102 from the first pixel portion 102a at FIG. 20 and from the second pixel portion 102b at FIGS. 29A and 29B. Further, the bonding electrically couples the first floating diffusion node FD1 to the transistor capacitor 112 via a long conductive path 120.

During use of the pixel sensor 102, charge accumulates at the PPD 106. Thereafter, the charge is transferred from the PPD 106 to the transistor capacitor 112, through the first floating diffusion node FD1. Further, the charge is transferred from the transistor capacitor 112 to the second floating diffusion node FD2, through the capacitor transfer transistor 114. As such, the transistor capacitor 112 and the capacitor transfer transistor 114 electrically separate the second floating diffusion node FD2 from the first floating diffusion node FD1.

By electrically separating the second floating diffusion node FD2 from the first floating diffusion node FD1, the transistor capacitor 112 and the capacitor transfer transistor 114 isolate the second floating diffusion node FD2 from parasitic capacitance at the first floating diffusion node FD1 and along the long conductive path 120 extending from the first floating diffusion node FD1 to the transistor capacitor 112. As a result, parasitic capacitance at the second floating diffusion node FD2 and hence at the gate electrode of the source-follower transistor 116 is decreased. This, in turn, increases a conversion gain of the source-follower transistor 116 and hence increases low-light performance.

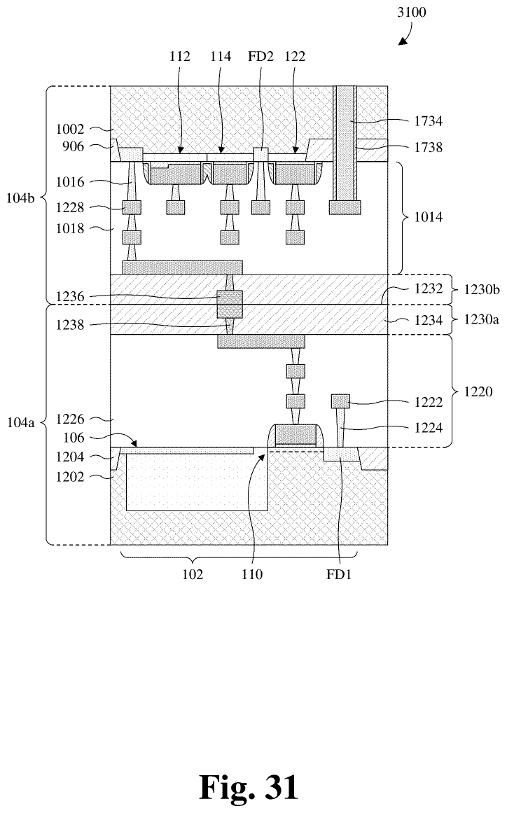

As illustrated by a cross-sectional view 3100 of FIG. 31, the second semiconductor substrate 1002 is thinned from an opposite side of the second semiconductor substrate 1002 as the second interconnect structure 1014. The thinning may, for example, be performed by a CMP and/or some other suitable planarization process.

Also illustrated by the cross-sectional view 3100 of FIG. 31, a TSV 1734 is formed extending through the second semiconductor substrate 1002 to the second interconnect structure 1014. Further, the TSV 1734 is formed separated from the second semiconductor substrate 1002 and the interconnect dielectric layer 1018 of the second interconnect structure 1014 by a TSV dielectric layer 1738. The TSV 1734 is conductive to provide electrical coupling to the second interconnect structure 1014 from a backside of the second semiconductor substrate 1002.

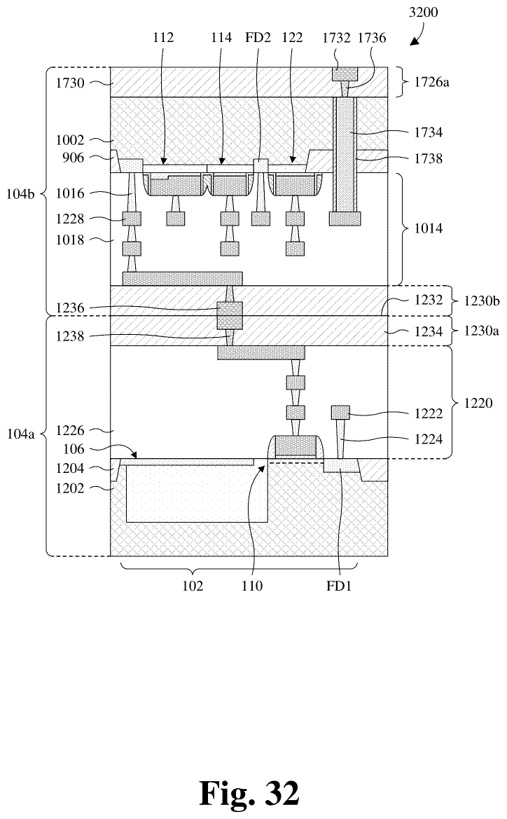

As illustrated by a cross-sectional view 3200 of FIG. 32, a third bond substructure 1726a is formed on the backside of the second semiconductor substrate 1002. The third bond substructure 1726a comprises a bond pad 1732 and a bond via 1736 in a bond dielectric layer 1730. The bond pad 1732 and the bond dielectric layer 1730 form a common bond surface, and the bond via 1736 extends from the bond pad 1732 to the TSV 1734.

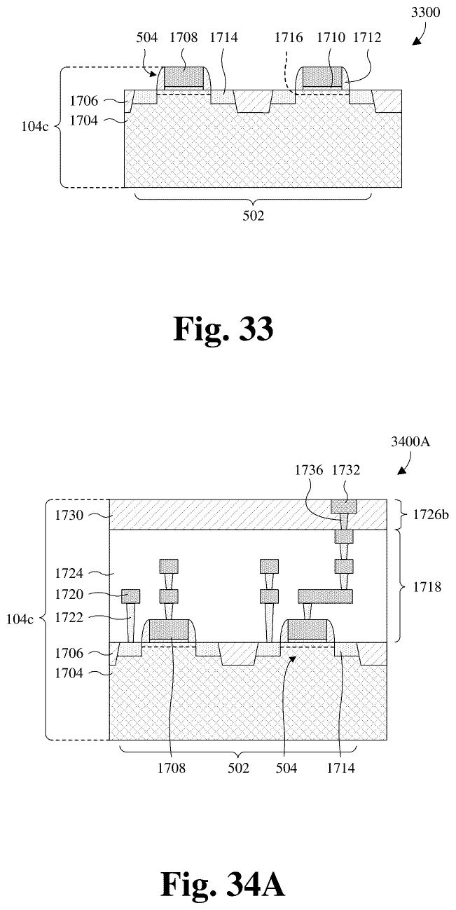

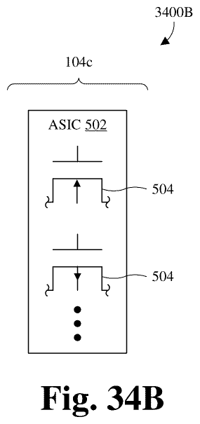

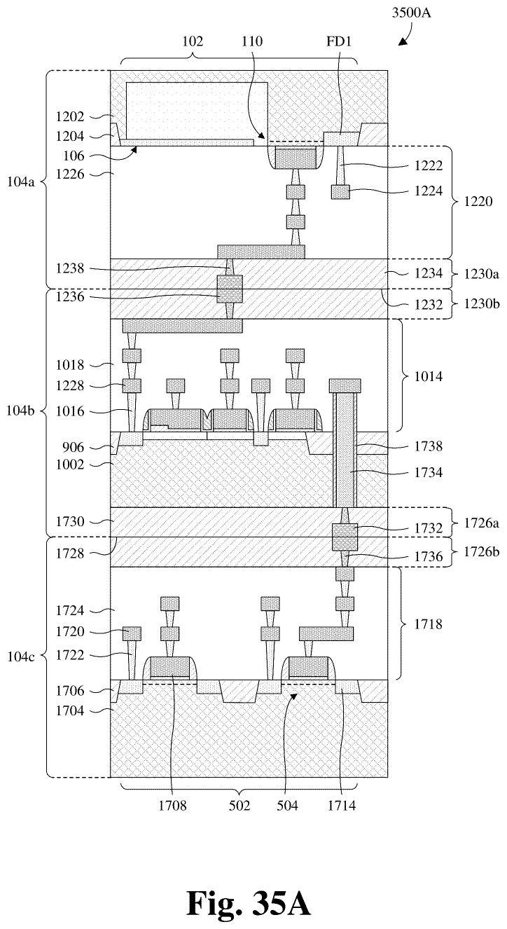

As illustrated by the views of FIGS. 33, 34A, and 34B, a third IC chip 104c comprising an ASIC 502 is formed.

Focusing on a cross-sectional view 3300 of FIG. 33, a plurality of transistors 504 are formed on a third semiconductor substrate 1704. The transistors 504 are on a frontside of the third semiconductor substrate 1704, laterally separated from each other by an isolation structure 1706. The isolation structure 1706 may, for example, be or comprise a STI structure or some other suitable isolation structure. Further, the transistors 504 comprise individual gate electrodes 1708, individual gate dielectric layers 1710, individual sidewall spacer structures 1712, individual pairs of source/drain regions 1714, and individual channels 1716.

The gate electrodes 1708 are stacked respectively with the gate dielectric layers 1710, which separate the gate electrodes 1708 from the third semiconductor substrate 1704. The sidewall spacer structures 1712 are dielectric and are respectively on sidewalls of the gate electrodes 1708. The pairs of source/drain regions 1714 are in the third semiconductor substrate 1704. Further, the source/drain regions of each pair of source/drain regions 1714 are separated by a corresponding one of the channels 1716.

Focusing on a cross-sectional view 3400A of FIG. 34A, and a circuit diagram 3400B of FIG. 34B, a third interconnect structure 1718 and a fourth bond substructure 1726b are formed. The third interconnect structure 1718 overlies and is electrically coupled to the transistors 504. The third interconnect structure 1718 comprises a plurality of wires 1720 and a plurality of vias 1722 in an interconnect dielectric layer 1724. The wires 1720 and the vias 1722 are conductive and are grouped respectively into a plurality of wire levels and a plurality of via levels that are alternatingly stacked to form conductive paths. The conductive paths interconnect the transistors 504 to form the ASIC 502 and/or additional circuits.

The fourth bond substructure 1726b is formed over and electrically coupled to the third interconnect structure 1718, and further comprises a bond pad 1732 and a bond via 1736 in a bond dielectric layer 1730. The bond pad 1732 and the bond dielectric layer 1730 form a common bond surface facing away from the third interconnect structure 1718, and the bond via 1736 extends from the bond pad 1732 to the third interconnect structure 1718.

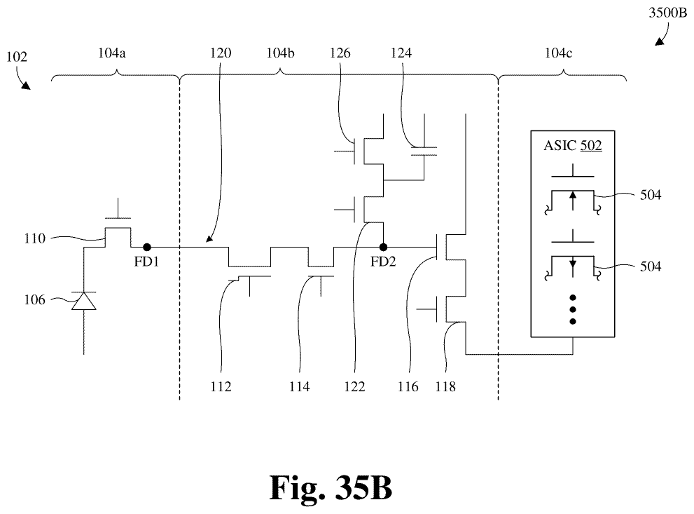

As illustrated by a cross-sectional view 3500A of FIG. 35A, and a circuit diagram 3500B of FIG. 35B, the structure of FIG. 32 is vertically flipped and is bonded to the third IC chip 104c of FIGS. 34A and 34B at a second bond interface 1728. The bonding electrically couples the pixel sensor 102 to the ASIC 502 and comprises both metal-to-metal bonding and dielectric-to-dielectric bonding. Further, the first semiconductor substrate 1202 is thinned from an opposite side of the first semiconductor substrate 1202 as the first interconnect structure 1220. The thinning may, for example, be performed by a CMP and/or the like.

While FIGS. 19A through 35B are described with reference to a method, it will be appreciated that the structures shown in these figures are not limited to the method but rather may stand alone separate of the method. While FIGS. 19A through 35B are described as a series of acts, it will be appreciated that the order of the acts may be altered in other embodiments. While FIGS. 19A through 35B illustrate and describe as a specific set of acts, some acts that are illustrated and/or described may be omitted in other embodiments. Further, acts that are not illustrated and/or described may be included in other embodiments.

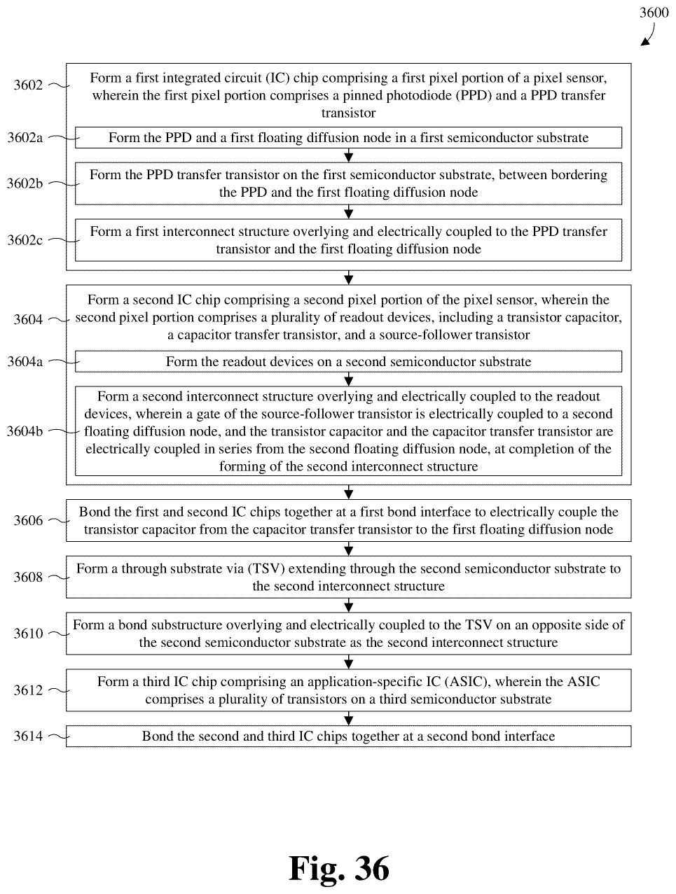

With reference to FIG. 36, a block diagram 3600 of some embodiments of the method of FIGS. 19A through 35B is provided.

At block 3602, a first IC chip comprising a first pixel portion of a pixel sensor is provided, wherein the first pixel portion comprises a PPD and a PPD transfer transistor. See, for example, FIGS. 19A, 19B, and 20. At block 3602a, the PPD and a first floating diffusion node are formed in a first semiconductor substrate. See, for example, FIGS. 19A and 19b. At block 3602b, the PPD transfer transistor is formed on the first semiconductor substrate, between bordering the PPD and the first floating diffusion node. See, for example, FIGS. 19A and 19B. At block 3602c, a first interconnect structure is formed overlying and electrically coupled to the PPD transfer transistor and the first floating diffusion node. See, for example, FIG. 20.

At block 3604, a second IC chip comprising a second pixel portion of the pixel sensor is formed, wherein the second pixel portion comprises a plurality of readout devices, including a transistor capacitor, a capacitor transfer transistor, and a source-follower transistor. See, for example, FIGS. 21A, 21B, 22-26, 27A, 27B, 28, 29A, and 29B. At block 3604a, the readout devices are formed on a second semiconductor substrate. See, for example, FIGS. 21A, 21B, 22-26, 27A, 27B, and 28. At block 3604b, a second interconnect structure is formed overlying and electrically coupled to the readout devices, wherein a gate of the source-follower transistor is electrically coupled to a second floating diffusion node, and the transistor capacitor and the capacitor transfer transistor are electrically coupled in series from the second floating diffusion node, at completion of the forming of the second interconnect structure. See for example, FIGS. 29A and 29B.

At block 3606, the first and second IC chips are bonded together at a first bond interface to electrically couple the transistor capacitor from the capacitor transfer transistor to the first floating diffusion node. See, for example, FIGS. 30A and 30B. As noted above, the transistor capacitor and the capacitor transfer transistor isolate the second floating diffusion node from parasitic capacitance at the first floating diffusion node and a long conductive path extending from the first floating diffusion node to the transistor capacitor. This improves a conversion gain of the source-follower transistor and hence improves pixel performance.

At block 3608, a TSV is formed extending through the second semiconductor substrate to the second interconnect structure. See, for example, FIG. 31.

At block 3610, a bond substructure is formed overlying and electrically coupled to the TSV on an opposite side of the second semiconductor substrate as the second interconnect structure. See, for example, FIG. 32.

At block 3612, a third IC chip comprising an ASIC is formed, wherein the ASIC comprises a plurality of transistors on a third semiconductor substrate. See, for example, FIGS. 33, 34A, and 34B.

At block 3614, the second and third IC chips are bonded together at a second bond interface. See, for example, FIG. 35.

While the block diagram 3600 of FIG. 36 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

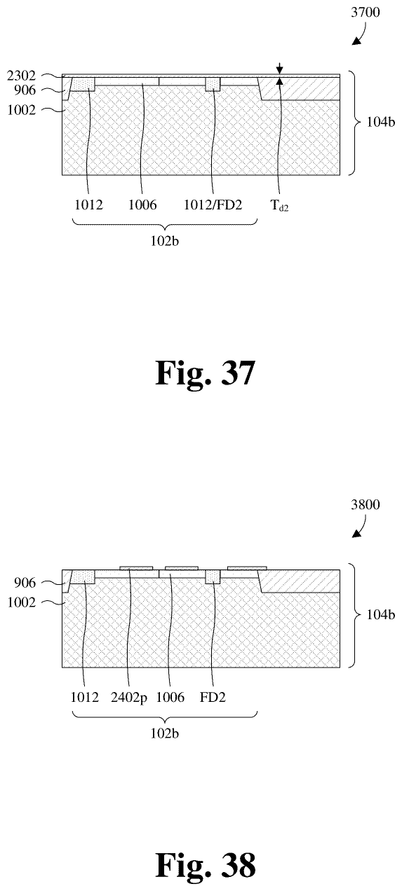

With reference to FIGS. 37 through 42B, a series of views of some first alternative embodiments of the method of FIGS. 19A through 35B is provided in which thicknesses of the first and second dielectric layers 2302, 2502 (compare FIGS. 23 and 25 to FIGS. 37 and 39) are switched. The method may, for example, be performed to form the stacked CMOS image sensor as in FIG. 17 or some other suitable stacked CMOS image sensor.

The method includes performing the acts described with regard to FIGS. 19A, 19B, and 20 to form the first IC chip 104a. Further, as illustrated by a cross-sectional view 3700 of FIG. 37, the acts described with regard to FIGS. 21A, 21B, 22, and 23 are performed to partially form the second IC chip 104b, except that the first dielectric layer 2302 is deposited with the second dielectric thickness T_{d2} (see, e.g., FIG. 25).

As illustrated by a cross-sectional view 3800 of FIG. 38, the first dielectric layer 2302 is patterned. The patterning is similar to the patterning described with regard to FIG. 24. However, instead of forming a single dielectric structure, the patterning forms a plurality of dielectric structures 2402p individual to and respectively overlying the wells 1006. Further, the patterning exposes portions of the second semiconductor substrate 1002 that are uncovered by the dielectric structures 2402p. The patterning may for example, be performed by a photolithography/etching process or by some other suitable patterning process.

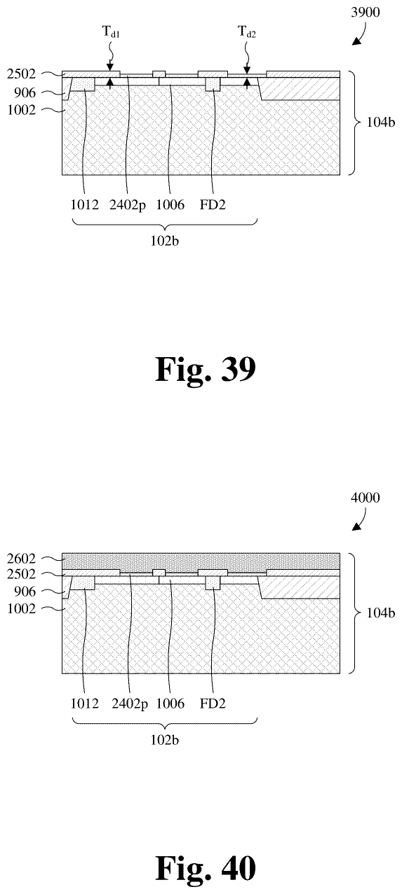

As illustrated by a cross-sectional view 3900 of FIG. 39, the second dielectric layer 2502 is deposited overlying the second semiconductor substrate 1002 as described with regard to FIG. 25, except that the second dielectric layer 2502 is deposited with the first dielectric thickness T_{d1} (see, e.g., FIG. 23). Further, the second dielectric layer 2502 is deposited by thermal oxidation or the like so it minimally deposits on the dielectric structure 2402p.

As illustrated by a cross-sectional view 4000 of FIG. 40, a conductive layer 2602 is deposited overlying the second dielectric layer 2502 and the dielectric structures 2402p. In some embodiments, a planarization is further performed to flatten a top surface of the conductive layer 2602. The planarization may, for example, be performed by a CMP and/or by some other suitable planarization process.

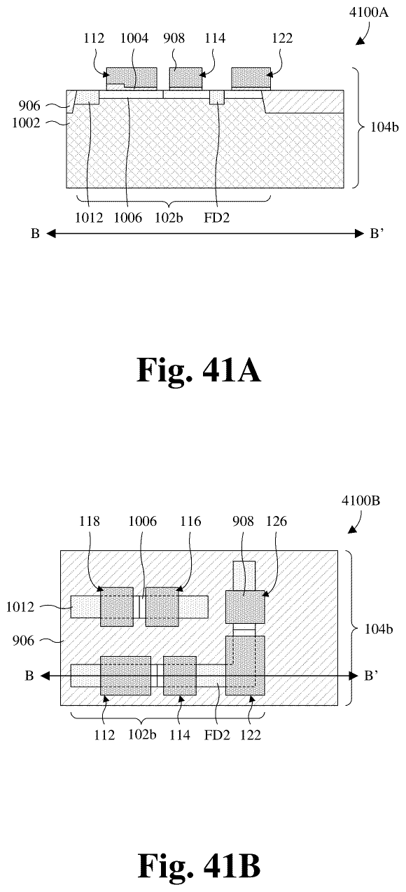

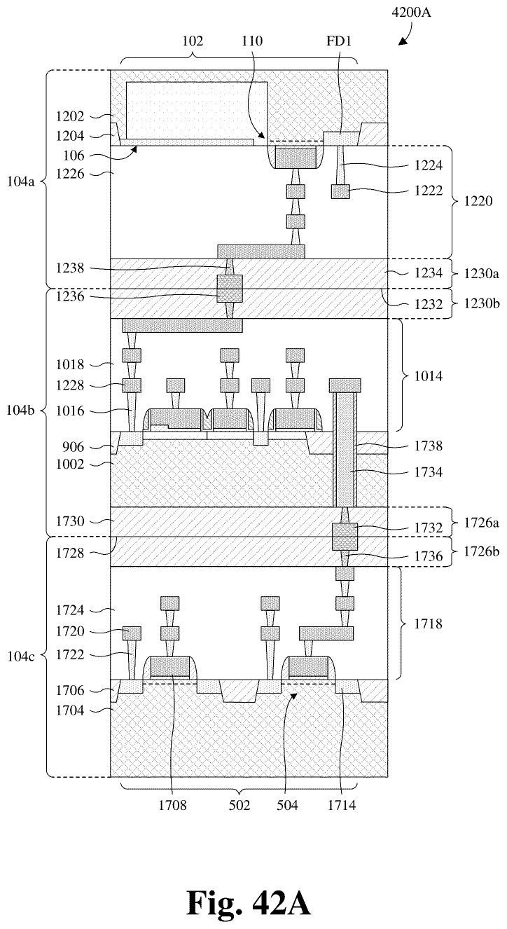

As illustrated by a cross-sectional view 4100A of FIG. 41A, and a top layout view 4100B of FIG. 41B, the conductive layer 2602, the second dielectric layer 2502, and the dielectric structures 2402p are patterned. The cross-sectional view 4100A of FIG. 41A may, for example, be taken along line B-B′ in the top layout view 4100B. The patterning is performed as described with regard to FIGS. 27A and 27B, except that the gate dielectric layers 1004 are formed from the dielectric structures 2402p, and the gate dielectric layer 1004 of the transistor capacitor 112 is further formed from the second dielectric layer 2502.

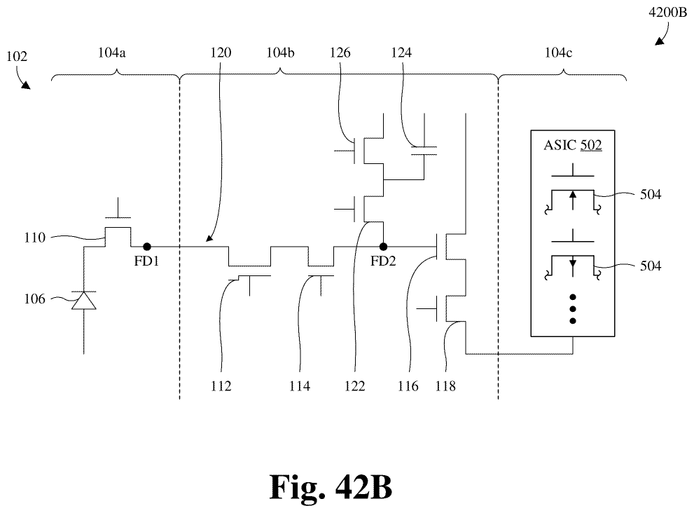

As illustrated by a cross-sectional view 4200A of FIG. 42A, and a circuit diagram 4200B of FIG. 42B, the acts described with regard to FIGS. 28, 29A, 29B, 30A, 30B, 31-33, 34A, 34B, 35A, and 35B are performed to complete the stacked CMOS image sensor.

While FIGS. 37 through 42B are described with reference to a method, it will be appreciated that the structures shown in these figures are not limited to the method but rather may stand alone separate of the method. While FIGS. 37 through 42B are described as a series of acts, it will be appreciated that the order of the acts may be altered in other embodiments. While FIGS. 37 through 42B illustrate and describe as a specific set of acts, some acts that are illustrated and/or described may be omitted in other embodiments. Further, acts that are not illustrated and/or described may be included in other embodiments.

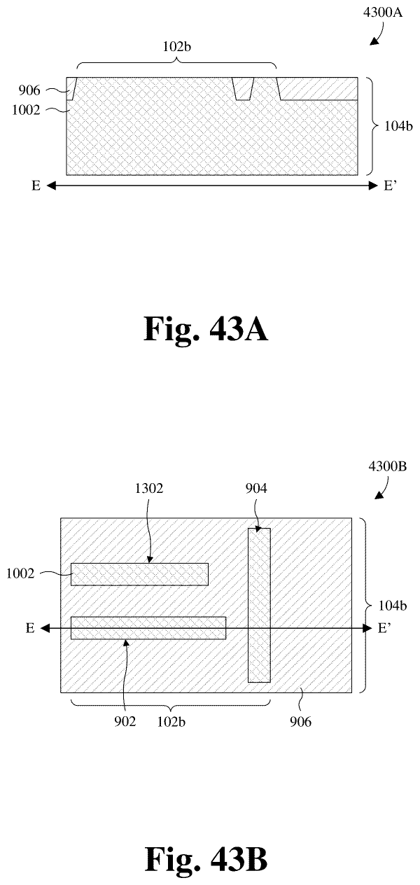

With reference to FIGS. 43A through 46B, a series of views of some second alternative embodiments of the method of FIGS. 19A through 35B is provided in which a layout of the second pixel portion 102b is varied (compare FIGS. 21A and 21B to FIGS. 43A and 43B). The method may, for example, be performed to form the stacked CMOS image sensor as in FIG. 18 or some other suitable stacked CMOS image sensor.

The method includes performing the acts described with regard to FIGS. 19A, 19B, and 20 to form the first IC chip 104a. Further, as illustrated by a cross-sectional view 4300A of FIG. 43A, and a top layout view 4300B of FIG. 43B, the acts described with regard to FIGS. 21A and 21B are performed to form an isolation structure 906. However, in contrast with FIGS. 21A and 21B, the isolation structure 906 has a different layout. The cross-sectional view 4300A may, for example, be taken along line E-E′ in the top layout view 4300B.

The isolation structure 906 surrounds and demarcates a first active semiconductor region 902, a second active semiconductor region 904, and a third active semiconductor region 1302. The first active semiconductor region 902 and the third active semiconductor region 1302 are elongated laterally in a first dimension. The second active semiconductor region 904 is on a common side of the first and third active semiconductor regions 902, 1302 and is elongated laterally in a second dimension orthogonal to the first dimension.

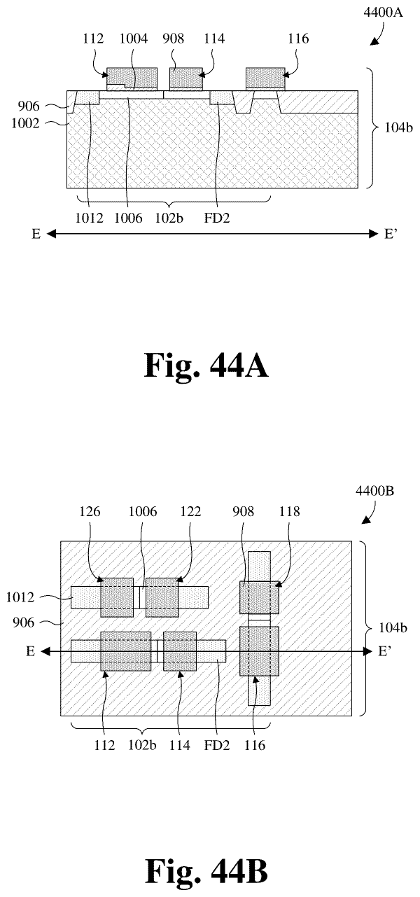

As illustrated by a cross-sectional view 4400A of FIG. 44A, and a top layout view 4400B of FIG. 44B, the acts described with regard to FIGS. 22-26, 27A, and 27B are performed to form a plurality of readout devices. However, the readout devices are formed with a different layout. The capacitor transfer transistor 114 and the LOFIC transistor 122 no longer share one of the source/drain regions 1012, which corresponds to the second floating diffusion node FD2.

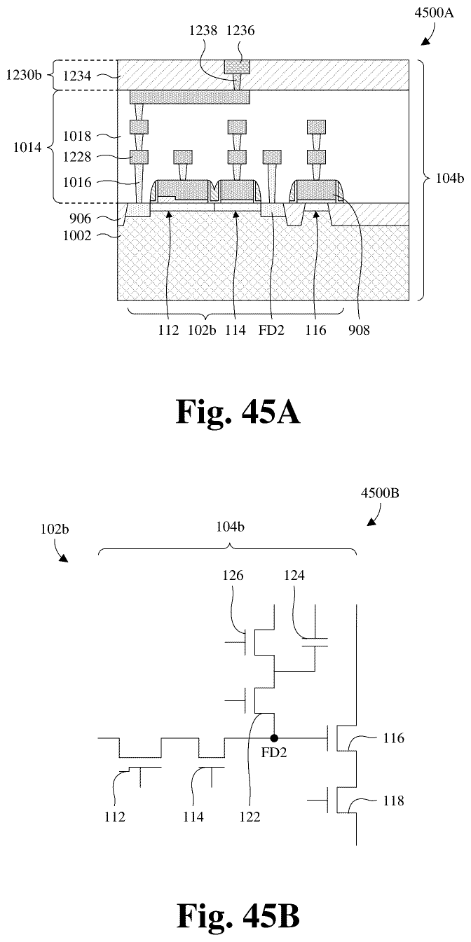

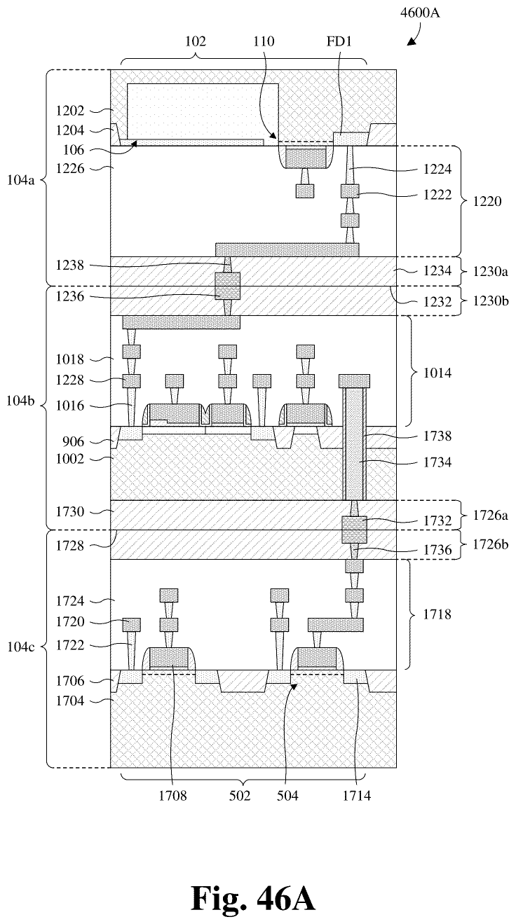

As illustrated by a cross-sectional view 4500A of FIG. 45A, and a circuit diagram 4500B of FIG. 45B, the acts described with regard to FIGS. 28, 29A, and 29B are performed to form the sidewall spacer structures 1010, the second interconnect structure 1014, and the second bond substructure 1230b. The second interconnect structure 1014 is similar to its counterpart in FIG. 29A, except that it has a different arrangement of wires and vias to electrically couple the second floating diffusion node FD2 to the gate electrode 908 of the source-follower transistor 116 and the source/drain region 1012 of the LOFIC transistor 122.

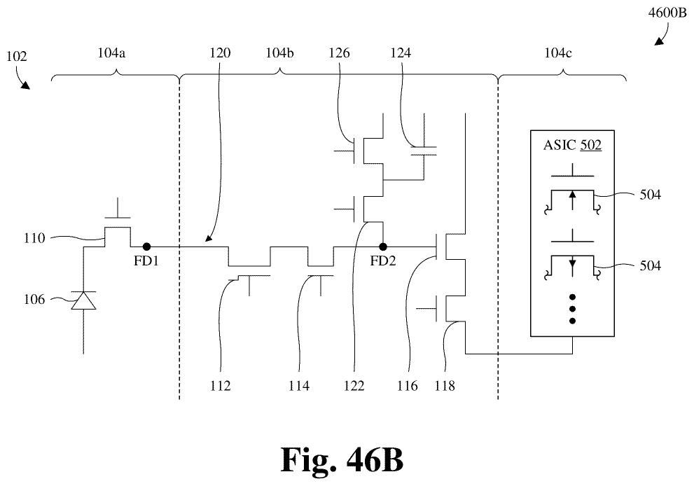

As illustrated by a cross-sectional view 4600A of FIG. 46A, and a circuit diagram 4600B of FIG. 46B, the acts described with regard to FIGS. 30A, 30B, 31-33, 34A, 34B, 35A, and 35B are performed to complete the stacked CMOS image sensor.

While FIGS. 43A through 46B are described with reference to a method, it will be appreciated that the structures shown in these figures are not limited to the method but rather may stand alone separate of the method. While FIGS. 43A through 46B are described as a series of acts, it will be appreciated that the order of the acts may be altered in other embodiments. While FIGS. 43A through 46B illustrate and describe as a specific set of acts, some acts that are illustrated and/or described may be omitted in other embodiments. Further, acts that are not illustrated and/or described may be included in other embodiments.

In view of the foregoing, various embodiments of the present disclosure are directed to a stacked CMOS image sensor comprising a pixel sensor for HCG and various methods for forming the same.

In some embodiments, the present disclosure provides an image sensor, including: a first IC chip; a second IC chip stacked with the first IC chip; and a pixel sensor spanning the first and second IC chips, wherein the pixel sensor includes a first transfer transistor and a photodetector at the first IC chip, and further includes a source-follower transistor, a transistor capacitor, and a second transfer transistor at the second IC chip; wherein the transistor capacitor and the second transfer transistor are electrically coupled in series from a source/drain region of the first transfer transistor to a gate electrode of the source-follower transistor. In some embodiments, the transistor capacitor is electrically between the source/drain region and the second transfer transistor. In some embodiments, the transistor capacitor includes a gate electrode, a first side, and a second side opposite the first side, and is electrically coupled to the source/drain region at the first side and is electrically coupled to the second transfer transistor at the second side, wherein the gate electrode of the transistor capacitor has a first thickness at the first side and a second thickness greater than the first thickness at the second side. In some embodiments, the second side of the transistor capacitor faces the second transfer transistor. In some embodiments, the pixel sensor further includes an additional transistor, wherein the second IC chip includes a semiconductor substrate and a trench isolation structure demarcating a first active semiconductor region in the semiconductor substrate and on which the transistor capacitor, the second transfer transistor, and the additional transistor are arranged, and wherein the additional transistor and the second transfer transistor share a common source/drain region. In some embodiments, the trench isolation structure demarcates a second semiconductor active region in the semiconductor substrate and on which the source-follower transistor is arranged, wherein the second active semiconductor region is spaced from the first active semiconductor region. In some embodiments, the transistor capacitor and the second transfer transistor share a sidewall spacer structure, which is between the transistor capacitor and the second transfer transistor and which is on individual gate-electrode sidewalls of the transistor capacitor and the second transfer transistor.

In some embodiments, the present disclosure provides an image sensor, including: a first substrate; a first pixel portion on the first substrate and including a photodetector; a second substrate underlying the first substrate; and a second pixel portion on the second substrate and including a source-follower transistor and a transistor capacitor, wherein the transistor capacitor electrically separates a gate electrode of the source-follower transistor from the first pixel portion, and wherein the transistor capacitor has a gate dielectric layer with a stepped profile; wherein the first pixel portion and the second pixel portion form a common pixel sensor. In some embodiments, the gate dielectric layer has a first thickness on a first side of the transistor capacitor that is electrically coupled to the first pixel portion and has a second thickness smaller than the first thickness on a second side of the transistor capacitor that is opposite the first side. In some embodiments, the second pixel portion further includes a transfer transistor electrically coupled from the gate electrode of the source-follower transistor to the second side of the transistor capacitor. In some embodiments the image sensor further includes: a trench isolation structure in the second substrate and demarcating a first active semiconductor region and a second active semiconductor region spaced from the first active semiconductor region, wherein the transistor capacitor is on the first active semiconductor region, and wherein the source-follower transistor is on the second active semiconductor region. In some embodiments, the first active semiconductor region has an L-shaped top geometry. In some embodiments, the trench isolation structure demarcates a third active semiconductor region spaced from the first and second active semiconductor regions, wherein the second pixel portion includes a reset transistor on the third active semiconductor region. In some embodiments, the first pixel portion further includes a transfer transistor configured to selectively transfer photo-generated charge from the photodetector to a first floating diffusion node, which is electrically coupled to a source/drain region of the transistor capacitor.

In some embodiments, the present disclosure provides a method for forming an image sensor, the method including: forming a first IC chip including a first pixel portion, wherein the first pixel portion includes a photodetector and a first transfer transistor electrically coupled from the photodetector to a first node; forming a second IC chip including a second pixel portion, wherein the second pixel portion includes a source-follower transistor, a transistor capacitor, and a second transfer transistor, and wherein a gate electrode of the source-follower transistor is electrically coupled to a second node; and bonding the first and second IC chips together to electrically couple the first and second pixel portions into a pixel sensor; wherein the second transfer transistor and the transistor capacitor are electrically coupled in series from the first node to the second node after the bonding. In some embodiments, the bonding includes both metal-to-metal bonding and dielectric-to-dielectric bonding. In some embodiments, the forming of the second IC chip includes: depositing a first dielectric layer over a substrate; patterning the first dielectric layer to form a dielectric structure and to expose the substrate laterally outside the dielectric structure; depositing a second dielectric layer on exposed portions of the substrate; depositing a conductive layer overlying the second dielectric layer; and patterning the second dielectric layer and the conductive layer to respectively form a gate dielectric layer and a gate electrode, which corresponds to the transistor capacitor and which overlies the dielectric structure and a portion the second dielectric layer that collectively form the gate dielectric layer. In some embodiments, the second dielectric layer has a smaller thickness than the first dielectric layer. In some embodiments, the second dielectric layer preferentially deposits on the exposed portions of the substrate compared to on the dielectric structure. In some embodiments, the method further includes: forming a third IC chip including an ASIC; and bonding the second and third IC chips together, such that the second IC chip is between the first and third IC chips and such that the ASIC is electrically coupled to the pixel sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a first integrated circuit (IC) chip;
a second IC chip stacked with the first IC chip; and
a pixel sensor spanning the first and second IC chips, wherein the pixel sensor comprises a first transfer transistor and a photodetector at the first IC chip, and further comprises a source-follower transistor, a transistor capacitor, and a second transfer transistor at the second IC chip;
wherein the transistor capacitor and the second transfer transistor are electrically coupled in series from a source/drain region of the first transfer transistor to a gate electrode of the source-follower transistor.

2. The image sensor according to claim 1, wherein the transistor capacitor is electrically between the source/drain region and the second transfer transistor.

3. The image sensor according to claim 1, wherein the transistor capacitor comprises a gate electrode, a first side, and a second side opposite the first side, and is electrically coupled to the source/drain region at the first side and is electrically coupled to the second transfer transistor at the second side, and wherein the gate electrode of the transistor capacitor has a first thickness at the first side and a second thickness greater than the first thickness at the second side.

4. The image sensor according to claim 3, wherein the second side of the transistor capacitor faces the second transfer transistor.

5. The image sensor according to claim 1, wherein the pixel sensor further comprises an additional transistor, wherein the second IC chip comprises a semiconductor substrate and a trench isolation structure demarcating a first active semiconductor region in the semiconductor substrate and on which the transistor capacitor, the second transfer transistor, and the additional transistor are arranged, and wherein the additional transistor and the second transfer transistor share a common source/drain region.

6. The image sensor according to claim 5, wherein the trench isolation structure demarcates a second semiconductor active region in the semiconductor substrate and on which the source-follower transistor is arranged, and wherein the second active semiconductor region is spaced from the first active semiconductor region.

7. The image sensor according to claim 1, wherein the transistor capacitor and the second transfer transistor share a sidewall spacer structure, which is between the transistor capacitor and the second transfer transistor and which is on individual gate-electrode sidewalls of the transistor capacitor and the second transfer transistor.

8. An image sensor, comprising:
a first substrate;
a first pixel portion on the first substrate and comprising a photodetector;
a second substrate underlying the first substrate; and
a second pixel portion on the second substrate and comprising a source-follower transistor and a transistor capacitor, wherein the transistor capacitor electrically separates a gate electrode of the source-follower transistor from the first pixel portion, and wherein the transistor capacitor has a gate dielectric layer with a stepped profile;
wherein the first pixel portion and the second pixel portion form a common pixel sensor.

9. The image sensor according to claim 8, wherein the gate dielectric layer has a first thickness on a first side of the transistor capacitor that is electrically coupled to the first pixel portion and has a second thickness smaller than the first thickness on a second side of the transistor capacitor that is opposite the first side.

10. The image sensor according to claim 9, wherein the second pixel portion further comprises a transfer transistor electrically coupled from the gate electrode of the source-follower transistor to the second side of the transistor capacitor.

11. The image sensor according to claim 8, further comprising:
a trench isolation structure in the second substrate and demarcating a first active semiconductor region and a second active semiconductor region spaced from the first active semiconductor region, wherein the transistor capacitor is on the first active semiconductor region, and wherein the source-follower transistor is on the second active semiconductor region.

12. The image sensor according to claim 11, wherein the first active semiconductor region has a substantially L-shaped top geometry.

13. The image sensor according to claim 11, wherein the trench isolation structure demarcates a third active semiconductor region spaced from the first and second active semiconductor regions, and wherein the second pixel portion comprises a reset transistor on the third active semiconductor region.

14. The image sensor according to claim 11, wherein the first pixel portion further comprises a transfer transistor configured to selectively transfer photo-generated charge from the photodetector to a first floating diffusion node, which is electrically coupled to a source/drain region of the transistor capacitor.

15. A method for forming an image sensor, the method comprising:
forming a first integrated circuit (IC) chip comprising a first pixel portion, wherein the first pixel portion comprises a photodetector and a first transfer transistor electrically coupled from the photodetector to a first node;
forming a second IC chip comprising a second pixel portion, wherein the second pixel portion comprises a source-follower transistor, a transistor capacitor, and a second transfer transistor, and wherein a gate electrode of the source-follower transistor is electrically coupled to a second node; and
bonding the first and second IC chips together to electrically couple the first and second pixel portions into a pixel sensor;
wherein the second transfer transistor and the transistor capacitor are electrically coupled in series from the first node to the second node after the bonding.

16. The method according to claim 15, wherein the bonding comprises both metal-to-metal bonding and dielectric-to-dielectric bonding.

17. The method according to claim 15, wherein the forming of the second IC chip comprises:
depositing a first dielectric layer over a substrate;
patterning the first dielectric layer to form a dielectric structure and to expose the substrate laterally outside the dielectric structure;
depositing a second dielectric layer on exposed portions of the substrate;
depositing a conductive layer overlying the second dielectric layer; and
patterning the second dielectric layer and the conductive layer to respectively form a gate dielectric layer and a gate electrode, which corresponds to the transistor capacitor and which overlies the dielectric structure and a portion the second dielectric layer that collectively form the gate dielectric layer.

18. The method according to claim 17, wherein the second dielectric layer has a smaller thickness than the first dielectric layer.

19. The method according to claim 17, wherein the second dielectric layer preferentially deposits on the exposed portions of the substrate compared to on the dielectric structure.

20. The method according to claim 15, further comprising:
forming a third IC chip comprising an application-specific integrated circuit (ASIC); and
bonding the second and third IC chips together, such that the second IC chip is between the first and third IC chips and such that the ASIC is electrically coupled to the pixel sensor.
